(19) United States
(12) Patent Application Publication
(10) Pub. No.: US 2025/0148138 A1
(43) Pub. Date: May 8, 2025

(54) COMPUTER AIDED DESIGN SYSTEM AND METHOD

(71) Applicant: Custom Equipment, LLC, Richfield, WI (US)

(72) Inventor: Brendan J. Foster, West Allis, WI (US)

(21) Appl. No.: 18/938,869

(22) Filed: Nov. 6, 2024

Related U.S. Application Data
(60) Provisional application No. 63/596,528, filed on Nov. 6, 2023.

(51) Int. Cl. G06F 30/12; G06F 30/23

(52) U.S. Cl. CPC G06F 30/12; G06F 30/23

(57) ABSTRACT

A computer-implemented method for computer aided design (CAD) includes maintaining a CAD template object having a first set of attributes and a second set of attributes. The first set of attributes include adjustable attributes and the second set of attributes include dependent attributes. The method includes presenting a graphic user interface (GUI) regarding the first set of attributes, the second set of attributes, and a sketch regarding the CAD template object; receiving an input regarding a setpoint value for an adjustable attribute; presenting an updated sketch of the CAD template object based on the first set of attributes and the second set of attributes; determining whether the setpoint value is valid; and, subsequent to determining whether the setpoint value is valid, generating, without additional user input, a set of solid body CAD objects based on the first set of attributes and the second set of attributes.

### CROSS REFERENCE TO RELATED APPLICATIONS

This application claims priority to and incorporates by reference U.S. Provisional Patent Application 63/596,528 filed on Nov. 6, 2023, entitled Improved Computer Aided Design Systems and Method.

### BACKGROUND

Computer-aided Design (CAD) is utilized to aid in the development of a design. CAD software can use graphics (e.g., vector-based graphics, raster graphics, etc.) to depict objects in 3-dimensional (3D) space, two-dimensional (2-D) space, or other dimensions. CAD software is often utilized by designers, engineers, makers, and manufacturers to facilitate product design, product development, and communication within a production chain.

### SUMMARY

The present disclosure relates generally to computing, computerized modeling, and user interfaces. More particularly, the present disclosure relates to systems and methods for improved computer aided design (CAD).

At least one implementation relates to a computer-implemented method for computer-aided design (CAD). The computer-implemented method includes maintaining a CAD template object having a first set of attributes and a second set of attributes. The first set of attributes includes adjustable attributes, and the second set of attributes include dependent attributes. The computer-implemented method includes presenting, via a user interface, a graphical user interface (GUI) regarding the first set of attributes, the second set of attributes, and a sketch regarding the CAD template object; receiving, via the user interface, an input regarding a setpoint value for an adjustable attribute of the first set of attributes; applying the setpoint value to the adjustable attribute of the first set of attributes; updating the second set of attributes based on the setpoint value applied to the adjustable attribute of the first set of attributes; presenting, via the user interface, an updated sketch of the CAD template object based on the first set of attributes and the second set of attributes; determining whether the setpoint value is valid by comparing a value of an attribute of the second set of attributes to a threshold value; and, subsequent to a determination that the setpoint value is valid, generating, without additional user input, a set of solid body CAD objects based on the first set of attributes and the second set of attributes.

At least one implementation relates to a non-transitory computer readable media having computer-executable instructions therein that, when executed by at least one processor, cause the at least one processor to perform operations for computer-aided design (CAD). The operations include: maintaining a CAD template object having a first set of attributes and a second set of attributes. The first set of attributes include adjustable attributes and the second set of attributes include dependent attributes. The operations include presenting, via a user interface, a graphic user interface (GUI) regarding the first set of attributes, the second set of attributes, and a sketch regarding the CAD template object; receiving, via the user interface, an input regarding a setpoint value for an adjustable attribute of the first set of attributes; applying the setpoint value to the adjustable attribute of the first set of attributes; updating the second set of attributes based on the setpoint value applied to the adjustable attribute of the first set of attributes; presenting, via the user interface, an updated sketch of the CAD template object based on the first set of attributes and the second set of attributes; determining whether the setpoint value is valid by comparing a value of an attribute of the second set of attributes to a threshold value; and, subsequent to a determination that the setpoint value is valid, generating, without additional user input, a set of solid body CAD objects based on the first set of attributes and the second set of attributes.

At least one implementation relates to a system for computer-aided design (CAD). The system includes: one or more memory devices storing instructions thereon that, when executed by one or more processors, cause the one or more processors to: maintain a CAD template object having a first set of attributes and a second set of attributes. The first set of attributes includes adjustable attributes, and the second set of attributes includes dependent attributes. The instructions further cause the at least one processor to: present, via a user interface, a graphic user interface (GUI) regarding the first set of attributes, the second set of attributes, and a sketch regarding the CAD template object; receive, via the user interface, an input regarding a setpoint value for an adjustable attribute of the first set of attributes; apply the setpoint value to the adjustable attribute of the first set of attributes; update the second set of attributes based on the setpoint value applied to the adjustable attribute of the first set of attributes; present, via the user interface, an updated sketch of the CAD template object based on the first set of attributes and the second set of attributes; determine whether the setpoint value is valid by comparing a value of an attribute of the second set of attributes to a threshold value; and, subsequent to a determination that the setpoint value is valid, generate, without additional user input, a set of solid body CAD objects based on the first set of attributes and the second set of attributes.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF THE DRAWINGS

FIG. 1 is a block diagram of a computing device configured for computer-aided design (CAD), according to an exemplary implementation;

FIG. 2 is a flow diagram of a process for CAD, according to some implementations;

FIG. 3 is another flow diagram of a process for CAD, according to some implementations;

FIG. 4 is a screenshot of a graphic user interface (GUI) illustrating a setpoint panel, a sketch panel, a check panel, a rules panel, an export panel, and an error panel, according to some implementations;

FIG. 5 is a screenshot of the GUI of FIG. 4 illustrating different adjustable attribute values, according to some implementations;

FIG. 6 is a screenshot of a GUI illustrating adjustable attributes and dependent attributes, according to some implementations;

FIG. 7 is a linkage diagram of a scissor stack template and a free body diagram of a portion of the scissor stack template, according to some implementations;

FIGS. 8A-8B are free body diagrams of the linkage diagram of FIG. 7, according to some implementations;

FIG. 9 is a screenshot of a GUI illustrating dependent attributes based on the adjustable attributes of FIG. 6, according to some implementations;

FIG. 10 is a screenshot of a GUI illustrating a sketch panel and a check panel based on the adjustable attributes of FIG. 6, according to some implementations;

FIG. 11 is a screenshot of a GUI illustrating a check panel based on the adjustable attributes of FIG. 6, according to some implementations;

FIG. 12 is a screenshot of a GUI illustrating a check panel based on the adjustable attributes of FIG. 6, according to some implementations;

FIG. 13 is a screenshot of a GUI illustrating a sketch panel, a setpoint panel, and a check panel, according to some implementations;

FIG. 14 is a screenshot of a GUI illustrating a sketch panel based on the adjustable attributes of FIG. 6, according to some implementations;

FIG. 15 is a screenshot of a GUI illustrating a sketch panel based on the adjustable attributes of FIG. 6, according to some implementations;

FIG. 16 is a screenshot of a GUI illustrating a sketch panel based on the adjustable attributes of FIG. 6, according to some implementations;

FIG. 17 is a screenshot of a GUI illustrating a solid body CAD model based on the adjustable attributes and dependent attributes of FIG. 6, according to some implementations;

FIG. 18 is a screenshot of a GUI illustrating a solid body CAD model with mates and tolerances based on the adjustable attributes of FIG. 6, according to some implementations;

FIG. 19 is a screenshot of a GUI illustrating a side view of the solid body CAD model of FIG. 18, according to some implementations; and

FIG. 20 is a screenshot of a GUI illustrating a solid body CAD model based on the adjustable attributes of FIG. 6 and applied to a finite element analysis, according to some implementations.

### DETAILED DESCRIPTION

Before turning to the figures, which illustrate the exemplary implementations in detail, it should be understood that the present application is not limited to the details or methodology set forth in the description or illustrated in the figures. It should also be understood that the terminology used herein is for the purpose of description only, but an overview of certain terms is helpful. For example, this disclosure is directed to digital models of subjects including, but not limited to, physical objects, physical assemblies of respective physical objects, and physical systems that include multiple physical objects. The digital models are implemented by use of Computer Aided Design technology, often referred to as “CAD.” CAD models, therefore, encompass visual digital representations of a subject. The subjects of CAD models may span across mechanical CAD models, electrical CAD models, and/or electromechanical CAD models. CAD models are often implemented using software “objects.” The CAD objects as described herein encompass the broadest plain meaning of the term “objects” and generally include a discrete set of computer programmed instructions having a state defined by variables and a function defined by associated methods of computing with the variables. For example, in non-limiting embodiments discussed below, a mechanical CAD model includes respective solid body CAD objects of mechanical parts or components. If the parts or components connect into a bigger assembly, the mechanical CAD model may combine solid body CAD objects into a CAD assembly object. The solid body CAD objects and overall CAD assembly objects may be stored in memory that is accessible by a computer processor to aid in future CAD modeling. CAD systems of this disclosure, therefore, can create generalized templates for CAD models by assessing these saved objects and abstracting certain useful parts of the objects into a more widely applicable CAD template object. CAD template objects, therefore, can serve as a foundation for a particular set of solid body CAD objects and/or CAD assembly objects in later particular applications of the technology.

As utilized herein, “CAD” (Computer Aided Design, Computer-Aided Design, Computer Aided Drafting, Computer Aided Design and Drafting, CADD) includes design, analysis, and product data management.

Described herein are systems and methods for improved CAD to better meet the needs of users. Typically, CAD involves a digital design environment and a digital model (i.e., a CAD model) that simulates one or more aspects of a tangible object. For example, a CAD model may simulate a part or a group of parts (e.g., an assembly of two or more parts). However, generating a CAD model can be difficult and burdensome. For example, a CAD model can require users to initialize, set, and modify parameters and/or parameter values. Additionally, CAD software usually consumes a large amount of computing power (e.g., processing power, graphics power, electronic memory, electricity, etc.) which can be costly. For example, some CAD applications (e.g., finite element analysis, fluid dynamic model analysis, etc.) can require a CAD system to process for several minutes, hours, or even days or weeks before yielding an output. Moreover, CAD files can be large and complicated and can burden file management systems. During iterative design, a CAD model may be repetitively resolved and rendered, or multiple instances of a CAD model may be generated, causing a significant computational load. In some situations, incremental changes to a CAD model can stack and push a design iteration outside of the initial set of design constraints and design criteria, which can be costly. For at least these reasons, a solution to the aforementioned technical problems is needed.

The systems and methods described herein provide solutions to these and other technical problems through a CAD platform that regulates the generation or modification of CAD models and related solid body CAD objects based on static design criteria. The CAD platform utilizes a processor 114 and associated computer memory 116 to provide and implement a CAD template object that provides the flexibility to validate parameter values against the static criteria prior to applying modified parameter values as attributes of a solid body CAD model. The CAD platform can automatically apply the validated parameter values to one or more solid body CAD model. Validating a set of parameter values for use in a solid body CAD model can improve efficiency and compliance to the constraints and criteria of the design. The CAD platform can avoid repetitive, burdensome, and time-consuming generation of a solid body CAD model for use within a solid body CAD environment.

In some implementations, a CAD model may be a mechanical CAD model. A mechanical model may be or include a solid body CAD model of a mechanical part or component, or groups of parts (e.g., an assembly or sub-assembly). Although the following description illustrates a mechanical CAD model, other types of CAD models (e.g., electrical models, electromechanical models, etc.) are contemplated.

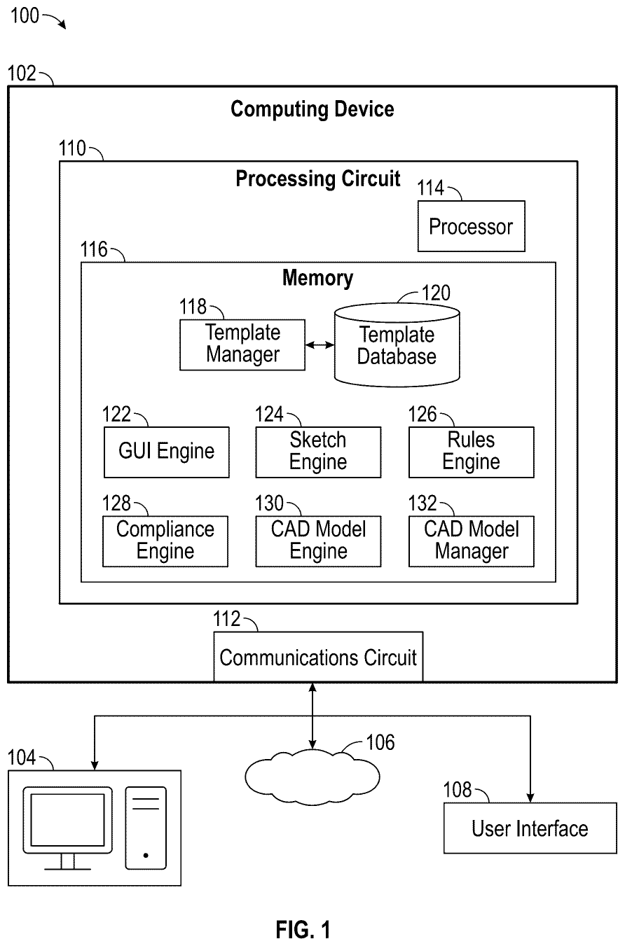

Referring now to FIG. 1, a CAD platform or system 100 includes a computing device 102, an administrative computing device 104, a cloud platform 106, and a user interface 108, according to some implementations. The computing device 102, the administrative computing device 104, the cloud platform 106, and the user interface 108 can be deployed on the same or different computing systems. In some implementations, the cloud platform 106, the administrative computing device 104, and user interface 108 are implemented off-premises relative to the computing device 102.

The computing device 102 includes a processing circuit 110 that is communicably coupled to communications circuit 112 such that the processing circuit 110 can send and receive data via communications circuit 112, according to some implementations. In some implementations, the communications circuit 112 facilitates communications between the computing device 102 and the administrative computing device 104, the cloud platform 106, and/or the user interface 108. In some implementations, the communications circuit 112 is or includes wired or wireless communications interfaces (e.g., jacks, transmitters, receivers, antennas, transceivers, wire terminals, etc.). In some implementations, the computing device 102 is implemented within a single computer (e.g., one housing, one chassis, etc.). In some implementations, the computing device 102 is distributed across multiple servers, computers, or computer clusters.

In some implementations, the processing circuit 110 includes a processor 114 and a memory 116. The processor 114 can be implemented as a general purpose processor, one or more field programmable gate arrays (FPGAs), a group of processing components, an application specific integrated circuit (ASIC), or other suitable electronic processing components. In some implementations, the processor 114 is a or includes an advanced RISC machine (ARM) based processor.

The memory 116 can be or include one or more devices (e.g., RAM, ROM, Flash memory, eROM, SSD storage, HDD storage, etc.) for storing data and/or computer code, instructions, for completing or facilitating the various processes, layers and modules described herein. In some implementations, the memory 116 is or includes volatile memory or non-volatile memory. The memory 116 can include database components, object code components, script components, or other instruction structures for supporting the various activities, tasks, and information structures described herein. In some implementations, memory 116 is communicably connected to processor 114 via the processing circuit 110 and includes computer code for executing (e.g., by the processing circuit 110 and/or the processor 114) one or more processes described herein.

Referring to FIG. 1, memory 116 includes a CAD template object manager 118 and a CAD template object database 120, according to some implementations. The CAD template object database 120 is configured to store one or more CAD template objects. In some implementations, the CAD template objects are based on a plurality of solid body CAD objects. For example, a CAD template object may include one or more attributes of a solid body CAD object. In some implementations, a solid body CAD object may be used in an overall solid body CAD model of a member. For example, the member may be a pipe having attributes such as wall thickness, length, inner diameter, outer diameter, material, etc., that can be varied by a user. In this example, the CAD template object may include a length attribute and a weight per unit length as an adjustable attribute, and weight as a dependent attribute. In some implementations, dependent attributes may be based on a relationship between one or more adjustable attributes of the CAD template object. For example, an inner diameter attribute and an outer diameter attribute can be used to determine the wall thickness of a simple pipe. In this example, the inner diameter and outer diameter may be supplied as adjustable attributes, and the wall thickness attribute may be applied as a dependent attribute. In some implementations, a CAD template object may be associated with a solid body CAD model that utilizes a group of solid body CAD objects. For example, a CAD template object may be a CAD assembly object. The CAD assembly object may include one or more CAD part template objects. In some implementations, a CAD assembly object may include one or more geometric constraints that geometrically constrain (e.g., mate) two or more CAD part objects in relative positions to one another.

In some implementations, the CAD template object manager 118 maintains a library of CAD template objects within the CAD template object database 120. The CAD template object manager 118 may create a CAD template object by selecting a subset of attributes of at least one solid body CAD object. The attributes of the CAD template object may be mapped to one or more adjustable attributes of the solid body CAD object. In some implementations, the CAD template object manager 118 is configured to detect one or more geometric relationships between attributes of a solid body CAD object. For example, the CAD template object manager 118 may read (e.g., scan, evaluate, analyze, etc.) a solid body CAD model and scrape out a subset of attributes to generate a set of attributes that simplify the solid body part file according to one or more simplifying assumptions to set up a CAD template object. As an example, applying this to a solid body CAD object of a pipe, the CAD template object manager 118 may be configured to scrape attributes such as a length attribute and a mass per unit length attribute. In some implementations, the CAD template object manager 118 may read a previously used CAD assembly object from memory and scrape attributes of the CAD assembly object (e.g., assembly-level attributes) and the constituent parts of the assembly (e.g., component-level attributes) to generate the CAD template object. The scrape behavior may be based on a prescribed set of rules (e.g., if it is a pipe scape attribute X, Y, Z) or an artificial intelligence (AI) or machine learning (ML) method based on previously configured CAD template objects. For example, the AI or ML method may be based on a model trained on pairs of solid body CAD models and CAD template objects.

In some implementations, when the CAD template object manager 118 selects (e.g., scrapes, etc.) a set of attributes from a solid body CAD model for use with a solid body CAD object, the selected set of attributes may be maintained within the CAD template object database 120. In some implementations, the CAD template object manager 118 maintains a mapping of the CAD template object to the solid body CAD object. In some implementations, the CAD template object manager 118 manages respective CAD template objects, such as but not limited to CAD assembly objects. In this non-limiting example, the CAD template object manager may compile a list of attributes for a respective CAD assembly object by amalgamating the attributes of the constituent parts of corresponding solid body CAD objects into a single set of attributes. For example, if two solid body CAD objects are mated together in a CAD assembly object, the CAD template object manager 118 may amalgamate the attributes of the two solid body CAD objects in a list of attributes of the CAD assembly object. In this example, the CAD assembly object's list of attributes may be or include an assembly attribute such as the count of constituents of the assembly object (in this particular example, it would be two), the geometric relationship(s) defined between the constituents (e.g., mate types, mate locations, mated features, etc.), and the attributes of the constituents such as pipe length and pipe weight per unit length, or other attributes. The CAD template object manager 118 may apply simplifying assumptions such as averages to determine a simplified set of attributes. For example, the CAD template object manager 118 may determine an averaged weight per unit length, estimated locations of point loads, or other simplifications that facilitate one or more performance estimations of the solid body CAD object. For example, the CAD template object manager 118 may identify attributes that simplify a solid body CAD model into a linkage or kinematic diagram. In some implementations, the set of attributes of the CAD template object is supplied to the CAD template object manager 118 along with the solid body CAD model (e.g., as a preconfigured pair). In such implementations, the CAD template object manager 118 may utilize the supplied CAD template object and solid body CAD object. It is important to note that although a specific example of a solid body CAD object for a pipe is utilized above, other solid body CAD objects are contemplated. For example, beams (e.g., I-beams, L-beams, etc.), rods, extruded parts, arcuate members, fasteners (e.g., bolts, screws, etc.), plates, machines (e.g., scissor lifts, vehicles, power equipment, tools, etc.), actuators (e.g., motors, hydraulic actuators, etc.), systems (e.g., a hydraulic system, an electrical system, a lighting system), circuitry, and many other solid body CAD objects are contemplated and should be considered within the scope of the present disclosure. The examples provided herein are for illustrative purposes only.

In some implementations, the CAD template object manager 118 can receive an indication of a user input from, for example, the user interface 108. In some implementations, the user interface 108 may be or include a display, a keyboard, a button, a joystick, a touch sensitive surface, a microphone, a camera, a speaker, or other user input/output (I/O) devices, or combinations thereof. In some implementations, the user interface 108 is implemented via a mobile device (e.g., cellphone, tablet, laptop, battery powered computing device, etc.). In some implementations, the user interface 108 is or includes a display (e.g., monitor, touch sensitive display, etc.), keyboard, and/or mouse (e.g., CAD mouse, a traditional mouse, etc.). Based on a received input, the CAD template object manager 118 may obtain the corresponding set of attributes (e.g., from the CAD template object database 120). For example, the selection may relate to an assembly (e.g., machine, scissor lift, vehicle, boom-lift, etc.), a sub-assembly of an assembly (e.g., scissor stack, transmission, power train, actuator, etc.), or a part (e.g., beam, rod, plate, bolt, etc.) of an assembly or sub-assembly of the assembly. In some implementations, the CAD template object manager 118 may provide the set of attributes to the GUI engine 122. In some implementations, a user may select a CAD template object (e.g., a scissor lift) from the CAD template object library and the CAD template object manager 118 may determine the corresponding set of attributes of the selected CAD template object and supply the set of attributes to the GUI engine 122.

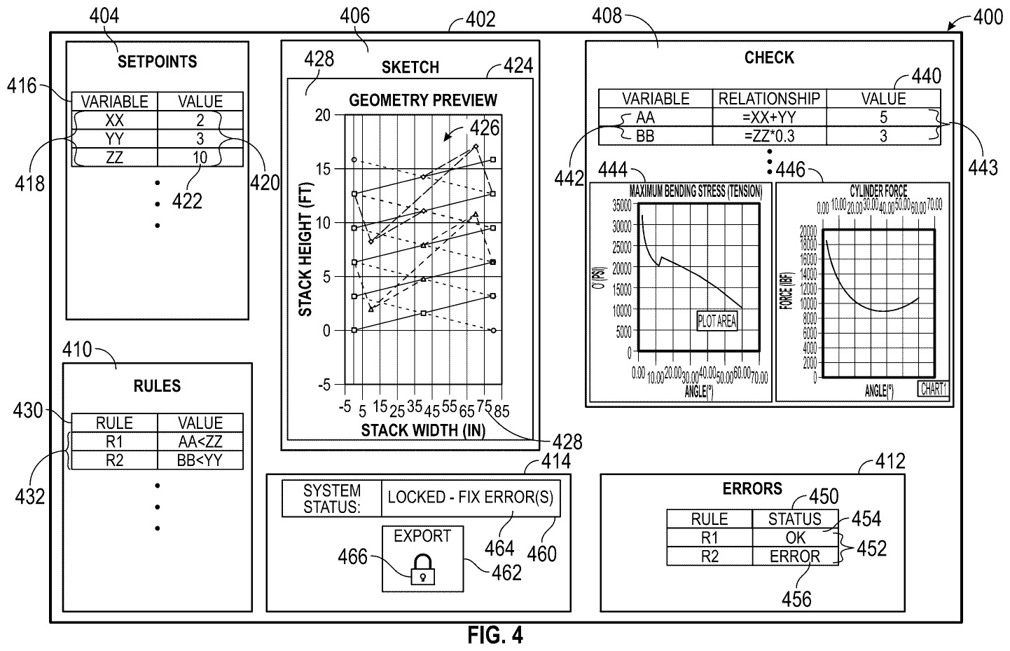

In some implementations, the GUI engine 122 may generate one or more screens for presentation via a display device (e.g., a light emitting diode (LED) display, an organic LED (OLED) display, a liquid crystal display (LCD), a mini LED display, a projector, etc.). In some implementations, the GUI engine 122 is configured to populate a variety of interactive fields based on the set of attributes provided by the CAD template object manager 118. In some implementations, the GUI engine 122 is configured to present a sequence of screens at set intervals or variable intervals. In some implementations, the GUI engine 122 is configured to generate screens in response to a user input. For example, the GUI engine 122 may generate a first screen including a set of attributes of a CAD template object, and based on a user interaction with an interactive element of the first screen, the GUI engine 122 may generate a second screen reflective of the aforementioned user interaction (e.g., present a dropdown, update a radio button, reflect an update to a numerical value or text string). In some implementations, the GUI engine 122 is configured to generate navigable screens that can be navigated by a user (e.g., scrolled through, zoomed, flipped through, panned, etc.). Illustrations of screens generated by the GUI engine 122 are described further with respect to FIGS. 4-20.

Referring to FIG. 1, the memory 116 includes a sketch engine 124 configured to generate depictions of the attributes of the CAD template object. In some implementations, the sketch engine 124 is configured to generate depictions of the attributes of the CAD template object in response to detecting an adjustment being made to one or more adjustable attribute values of the CAD template object. For example, the sketch engine 124 may display a first depiction of the geometry of the CAD template object based on an initial set of values (e.g., placeholder values) of the attributes of the CAD template object, and, responsive to a change made to one or more values of the adjustable attributes, generate an updated depiction of the CAD template object that reflects the changed value(s). For example, if a length attribute is changed from 1 unit length (e.g., inch, meter, foot, centimeter, micron, etc.) to 10 unit length, the sketch engine 124 may update the depiction to reflect the change in length. In some implementations, the sketch engine 124 is configured to update the depiction in real-time (or close to real time). For example, the sketch engine 124 may automatically (e.g., without requiring additional user input) update the depiction of the CAD template object when a value of an attribute is changed (e.g., within one second). Advantageously, adjustments made to the values of the attributes can be processed by the sketch engine 124 rapidly due to the CAD template object being based on fewer attributes (e.g., simplified attributes) compared to a solid body CAD model.

In some implementations, the memory 116 includes a rules engine 126. The rules engine 126 is configured to manage one or more rules or relationships involving the attributes of the CAD template object. For example, the rules engine 126 may determine one or more values of a dependent attribute based on changes to the adjustable attribute(s) on which the dependent attribute depends. In some implementations, the rules engine 126 determines values for mechanical performance (e.g., loading, stresses, deflections, degrees of freedom, overall dimensions, etc.) based on the adjustable attributes of the CAD template object and dependent attributes of the CAD template object. For example, the rules engine 126 may determine estimated or exact values for heights (e.g., overall height, height ranges, height ratios, etc.), widths, thicknesses, weights, loads, stresses, loading locations, critical load locations, torsional stresses, thermal loads, vibrations, fatigue, life, angular ranges, fluid dynamic calculations, etc. In some implementations, the rules engine 126 is configured to operate to a resolution of less than 1% of numerical values. In some implementations, the rules engine 126 is configured to operate with a resolution of less than 2% of adjustable attribute values.

In some implementations, the rules engine 126 manages one or more standards, constraints, or criteria. For example, the rules engine 126 may be configured to obtain one or more standards, constraints, or criteria from the administrative computing device 104 or the cloud platform 106. For example, the rules engine 126 may manage one or more threshold values against which one or more adjustable attributes or dependent attributes are compared. For example, the rules engine 126 may access a set of rules and standards such as United Laboratories (UL) standards, American National Standards Institute® (ANSI®) standards, department of transportation (DOT) rules, factors of safety, Canadian standards, European standards, CSA Group™ standards, engineering guidelines, and/or design criteria (e.g., design goals, design goals dictated by a marketing team, etc.). In some implementations, the rules engine 126 determines estimated or exact values for weight, overall geometric dimensions (e.g., height, width, thickness, etc.), motion ranges, actuator loads, and minimum stresses and maximum stresses.

Referring to FIG. 1, the memory 116 includes a compliance engine 128, according to some implementations. The compliance engine 128 is configured to determine the validity of the values of the attributes of the CAD template object. For example, the compliance engine 128 may compare the attribute values against one or more standards, constraints, or criteria. More specifically, the compliance engine 128 is configured to compare the values of attributes against one or more threshold values prescribed by the safety standards, design constraints, or design criteria. For example, the compliance engine 128 may compare a value of a maximum height to one or more safety standards, design constraints, or design criteria that prescribe a threshold value for the maximum height. As another example, the compliance engine 128 may compare a value of a total weight attribute against a maximum weight threshold value. Further in this example, if the value of the overall weight attribute exceeds the weight threshold value, the compliance engine may determine that the set of attribute values of the CAD template object is not valid (i.e., invalid, noncompliant), according to some implementations. In some implementations, based on the determination that the set of values of the attributes of the CAD template object is invalid, the compliance engine 128 may prevent the values from being applied to a solid body CAD object, according to some implementations. For example, the compliance engine 128 may disable a communication link between a solid body CAD object and the CAD template object, or disable a user accessible trigger (e.g., button, slider, etc.) configured to command the CAD model engine 130 to generate or update a solid body CAD model based on the attribute values of the CAD template object. In some implementations, the compliance engine 128 may command the GUI engine 122 to display an alert regarding the invalid value(s) of the CAD template object in response to a determination that the values of the attributes are invalid. For example, the GUI engine 122 may display an error message, change the color of displayed text, highlight a field, display a lock icon, flash a sequence of colors, present an error code, etc. in response to the command. In some implementations, the compliance engine 128 may command the GUI engine 122 to display an alert after receiving an indication of a user input instructing the compliance engine 128 to generate a solid body CAD object based on the values of the attributes of the CAD template object. In some implementations, the compliance engine 128 is configured to provide the values of the attributes of the CAD template object to the CAD template object manager 118, responsive to a determination that the values of the attributes of the CAD template object are valid. In such implementations, the CAD template object manager 118 can apply the attributes of the CAD template object to a solid body CAD object based on the mapping of the attribute values between the CAD template object and the solid body CAD object.

In some implementations, the memory 116 includes a CAD model engine 130. The CAD model engine 130 is configured to generate and manage solid body CAD objects. In some implementations, the CAD model engine 130 receives a set of values of the attributes of the CAD template object via the CAD template object manager 118. Based on the values of the attributes of the CAD template object, the CAD model engine 130 may apply one or more of the values to one or more attributes of a solid body CAD object. For example, the CAD model engine 130 may generate one or more solid body CAD part objects and one or more solid body CAD assembly objects. In some implementations, the CAD model engine 130 may update a solid body CAD model by applying the set of attribute values to the solid body CAD model.

In some implementations, the CAD model engine 130 is configured to obtain (e.g., call via an API) the values of the attributes of the CAD template object and apply the values to a solid body CAD model (e.g., set via an API). In some implementations, the CAD model engine 130 includes running a script configured to trigger communications between two independent computer programs (e.g., computer applications, computer services, etc.). For example, the CAD model engine 130 may run a script that instructs communication between a database or spreadsheet management software such as Microsoft® Excel® and a solid body CAD modeling software such as SolidWorks® or Autodesk® Inventor®. In some implementations, the CAD model engine 130 may include computer executable code written at least partially in an object-oriented programming language such as the Visual Basic® programming language. Although specific examples of computer applications and a programming language is stated herein, other computer applications and programming languages are contemplated and should be considered within the scope of the present disclosure.

In some implementations, the CAD model engine 130 is configured to create one or more solid body CAD objects based on the values of one or more attributes of the CAD template objects. The CAD model engine 130 may assign one or more tags to a generated solid body CAD object based on the attributes of the CAD template object utilized to generate the solid body CAD object. For example, the CAD model engine 130 may assign a name to the generated solid body CAD object according to one or more geometric constraints of the CAD template object. For example, the CAD model engine 130 may assign a tag (e.g., name) such as “Assemblyl_ABC” to a first solid body CAD object, and “Assemblyl_DEF” to a second solid body CAD object. Further in this example, the CAD model engine 130 may generate a solid body CAD assembly object tagged “Assemblyl” and, based on matching or identifying the tags assigned to the first solid body CAD object and the second solid body CAD object, insert the first solid body CAD object and the second solid body CAD object into the “Assemblyl” solid body CAD assembly object.

In some implementations, the CAD model engine 130 may apply one or more geometric constraints between a first solid body CAD object and a second solid body CAD object based on information included in a solid body CAD object's tag. For example, the CAD model engine 130 may automatically apply a geometric constraint (e.g., a flush mate, an edge mate, a pivot mate, a pin, etc.) between a first feature (e.g., edge, point, surface, plane, etc.) of the first solid body CAD object and a feature of the second solid body CAD object according to one or more rules based on the information included in the tags. In this way, the CAD model engine 130 can generate solid body CAD assembly objects based on repeated patterns configured via the CAD object template, according to some implementations. For example, if the solid body CAD object on which the CAD template object is based includes four rods pinned together at their ends in a square shape, and the CAD template object simplifies the solid body CAD object into a four bar linkage, if a fifth link is added to the linkage of the CAD template object, the CAD model engine 130 can generate the corresponding fifth rod (as a new solid body CAD object) and automatically apply mates between features of the fifth rod and features of the other rods according to the attributes of the CAD template object. Further in this example, if a user changes the linkage count to three (e.g., removing a link), the CAD model engine 130 can generate a solid body CAD assembly object of three rod objects based on the manipulations made to the CAD template object.

In some implementations, the CAD model engine 130 is configured to generate multiple solid body CAD assembly objects based on the values of the attributes of the CAD template object. In some implementations, the CAD model engine 130 is configured to create a manufacture-type solid body CAD assembly object and/or an analysis-type solid body CAD assembly object. The manufacture-type solid body CAD assembly object may include attributes that accommodate real-world manufacturing considerations, such as soft values (e.g., tolerances) for attributes of the solid body CAD model. The analysis-type solid body CAD assembly object may have strict or fixed values that facilitate analysis and simulation of the solid body CAD assembly object. In some implementations, the analysis-type solid body CAD assembly object includes fully constrained motion and/or mesh definitions for a finite element analysis. Advantageously, the computing device 102 can automatically generate one or more manufacture-type solid body CAD objects and one or more analysis-type solid body CAD objects based on the CAD template object, which can save time, computational resources, and prevent human errors (e.g., typographical errors, transcription errors, etc.).

In some implementations, the memory 116 includes a CAD model manager 132. The CAD model manager 132 may manage one or more solid body CAD objects, according to some implementations. In some implementations, the CAD model manager 132 may apply a solid body CAD object to one or more CAD analysis tools (e.g., finite element analysis). The CAD model manager 132 may return analysis results to the GUI engine 122. The GUI engine 122 may present the results via one or more screens presented on a display device of the user interface 108. In some implementations, the CAD model manager 132 facilitates tuning the generated solid body CAD objects independently of the CAD template object.

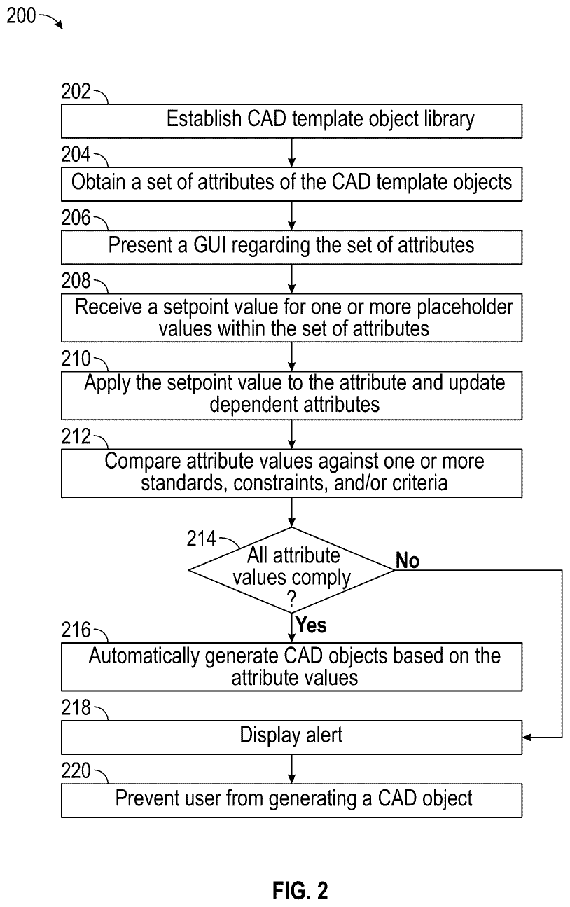

Referring now to FIG. 2, a process 200 for CAD is shown, according to an exemplary implementation. The process 200 can be performed by the CAD platform 100 and/or the components of the CAD platform 100.

In step 202, the process 200 includes maintaining one or more CAD template objects including a first set of attributes and a second set of attributes, where the first set of attributes includes adjustable attributes, and the second set of attributes includes attributes dependent on one or more adjustable attributes of the first set of attributes. In some implementations, the CAD template object manager 118 establishes a CAD template object library within the CAD template object database 120. In some implementations, the CAD template object library includes CAD template objects provided by the administrative computing device 104. For example, the administrative computing device 104 may maintain a repository of previously created CAD template objects (e.g., to be shared among co-workers or collaborators). In some implementations, the CAD template object manager 118 may create a CAD template object by selecting a subset of attributes of at least one solid body CAD object. The selected attributes may support estimations of mechanical performance characteristics. In some implementations, the CAD template object manager 118 and/or the CAD model engine 130 establish and maintain a mapping between the attributes of the CAD template object and the one or more attributes of the solid body CAD object. In some implementations, the first set of attributes are adjustable attributes, and the second set of attributes are dependent attributes that depend from one or more adjustable attributes.

In step 204, the process 200 includes obtaining a set of attributes of a CAD template object, according to some implementations. In some implementations, the set of attributes is based on a user selection of a CAD template object from the CAD template object library. In some implementations, the CAD template object manager 118 obtains the set of attributes of the CAD template object and maintains a mapping between the attributes of the CAD template object and the one or more attributes of corresponding solid body CAD objects.

In step 206, the process 200 includes presenting a GUI regarding the first set of attributes, the second set of attributes, and a sketch regarding the CAD template object, according to some implementations. In some implementations, GUI is configured to present the first set of attributes and the second set of attributes in one or more tables. In some implementations, the GUI is configured to present the sketch including a kinematic diagram based on the first set of attributes and the second set of attributes of the CAD template object. In some implementations, the GUI engine 122 may generate one or more screens for presentation via a display device of the user interface 108. In some implementations, the GUI engine 122 generates one or more tables including the first set of attributes and the second set of attributes of the CAD template object. In some implementations, one or more of the values of the first set of attributes and the second set of attributes are initially set to placeholder values (e.g., arbitrary values, empty values, zeros, etc.). In some implementations, the sketch engine 124 is configured to generate a depiction of the attributes of the CAD template object set to the placeholder values. In some implementations, the sketch comprises a stick diagram (e.g., kinematic diagram).

In step 208, the process 200 includes receiving an input regarding a setpoint value for an adjustable attribute of the first set of attributes, according to some implementations. In some implementations, the user input may be received via the user interface 108. In some implementations, the user interface 108 may be or include a display, a keyboard, a button, a joystick, a touch sensitive surface, a microphone, a camera, a speaker, or other user input/output (I/O) devices, or combinations thereof. In some implementations, the user interface 108 is implemented via a mobile device (e.g., cellphone, tablet, laptop, battery powered computing device, etc.). In some implementations, the user interface 108 is or includes a display (e.g., monitor, touch sensitive display, etc.), keyboard, and/or mouse (e.g., CAD mouse, a traditional mouse, etc.).

In step 210, the process 200 includes applying the setpoint value to the adjustable attribute of the first set of attributes, according to some implementations. In some implementations, the step 210 includes updating the second set of attributes based on the setpoint value applied to the adjustable attribute of the first set of attributes. For example, the rules engine 126 may update one or more values based on the adjustable attribute values. In some implementations, step 210 includes presenting, via the user interface, an updated sketch of the CAD template object based on the first set of attributes and the second set of attributes.

In step 212, the process 200 includes determining whether the setpoint value for the adjustable attribute is valid by comparing a value of an attribute of the second set of attributes to a threshold value, according to some implementations. In some implementations, step 212 includes comparing attribute values against one or more standards, constraints, and/or criteria. In some implementations, step 212 is performed by the compliance engine 128. For example, the compliance engine 128 may compare one or more attribute values of the CAD template object to one or more threshold values based on one or more rules.

In step 214, the process 200 includes determining whether the values of the set of attributes comply with the standards, constraints, and/or criteria, according to some implementations. In some implementations, based on a determination that the values of the attributes of the CAD template object comply with the standards, constraints, and criteria, the process 200 continues with a step 216. In some implementations, based on a determination that the values of the attributes of the CAD template object do not comply with the standards, constraints, and criteria, the process 200 continues with a step 218.

In step 216, the process 200 includes generating, without additional user input, one or more solid body CAD objects based on the first set of attributes and the second set of attributes, according to some implementations. In some implementations, step 216 includes automatically generating CAD objects based on the attribute values of the CAD template object. In some implementations, step 216 includes generating solid-body CAD objects based on the values of the attributes of the CAD template object. In some implementations, step 216 is performed by the CAD model engine 130.

In step 218, the process 200 includes presenting an alert regarding the invalid setpoint value, according to some implementations. In some implementations, the alert may be or include text, shapes, colors, animations, audible sounds, and/or tactile feedback. In some implementations, the compliance engine 128 may command the GUI engine 122 to display an alert regarding the invalid value(s) of the CAD template object in response to a determination that the values of the attributes are invalid. For example, the GUI engine 122 may display an error message, change the color of displayed text, highlight a field, display a lock icon, flash a sequence of colors, present an error code, etc. in response to the command. In some implementations, the compliance engine 128 may command the GUI engine 122 to display an alert after receiving an indication of a user input instructing the compliance engine 128 to generate a solid body CAD object based on the values of the attributes of the CAD template object.

In step 220, the process 200 includes preventing values of the second set of attributes from being applied to a CAD object, according to some implementations. In some implementations, based on the determination that the set of values of the attributes of the CAD template object is invalid, the compliance engine 128 may prevent the values from being applied to a solid body CAD object, according to some implementations. For example, the compliance engine 128 may disable a communication link between a solid body CAD object and the CAD template object, or disable a user accessible trigger (e.g., button, slider, etc.) configured to command the CAD model engine 130 to generate or update a solid body CAD model based on the attribute values of the CAD template object.

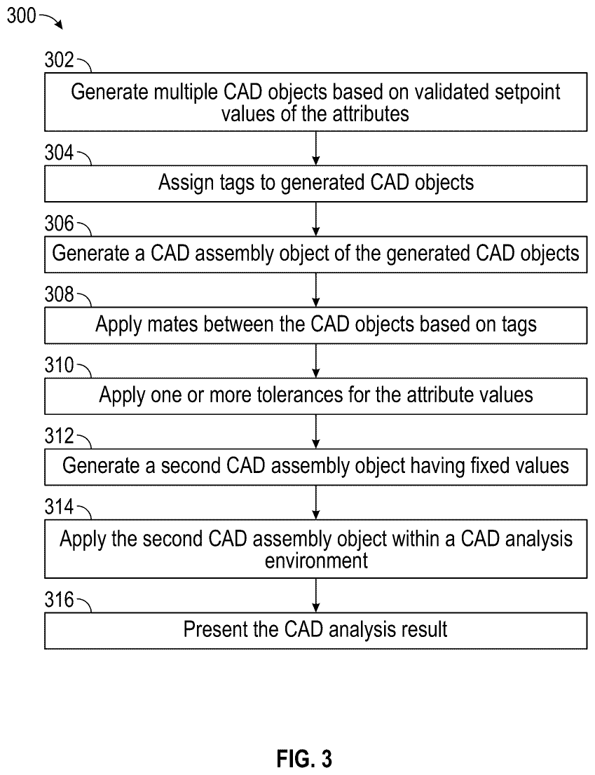

Referring now to FIG. 3, a process 300 for CAD is shown, according to an exemplary implementation. The process 300 can be performed by the CAD platform 100 and/or the components of the CAD platform 100.

In step 302, the process 300 includes generating multiple CAD objects based on validated setpoint values of the attributes, according to some implementations. In some implementations, the validated setpoint values of the attributes are the values of the first set of attributes and the second set of attributes of step 214 of process 200.

In step 304, the process 300 includes assigning a unique tag to each of the one or more solid body CAD objects, where the unique tag is based on the first set of attributes and the second set of attributes, according to some implementations. In some implementations, step 304 includes assigning tags to generated solid body CAD objects. In some implementations, the CAD model engine 130 assigns one or more tags to a generated solid body CAD object based on the attributes of the CAD template object utilized to generate the solid body CAD object. For example, the CAD model engine 130 may assign a name to the generated solid body CAD object according to one or more geometric constraints of the CAD template object. For example, the CAD model engine 130 may assign a tag (e.g., name) such as “Assemblyl_ABC” to a first solid body CAD object, and “Assemblyl_DEF” to a second solid body CAD object.

In step 306, the process 300 includes creating a solid body CAD assembly object based on the attribute values of the CAD template object, according to some implementations. In some implementations, step 306 includes generating a manufacture-type solid body CAD assembly object. In some implementations, the CAD model engine 130 is configured to generate one or more solid body CAD assembly objects based on the values of the attributes of the CAD template object. In some implementations, the CAD model engine 130 is configured to create a manufacture-type solid body CAD assembly object. The manufacture-type solid body CAD assembly object may include attributes that accommodate real-world manufacturing considerations, such as soft values (e.g., tolerances) for attributes of the solid body CAD model.

In step 308, the process 300 includes automatically applying, based on the unique tags, a one or more geometric relationships between the one or more CAD objects, according to some implementations. In some implementations, step 308 includes applying mates between the CAD objects based on tags. In some implementations, the CAD model engine 130 may apply one or more geometric constraints between a first solid body CAD object and a second solid body CAD object based on information included in a solid body CAD object's tag. For example, the CAD model engine 130 may automatically apply a geometric constraint (e.g., a flush mate, an edge mate, a pivot mate, a pin, etc.) between a first feature (e.g., edge, point, surface, plane, etc.) of the first solid body CAD object and a feature of the second solid body CAD object according to one or more rules based on the information included in the tags. In this way, the CAD model engine 130 can generate solid body CAD assembly objects based on repeated patterns configured via the CAD object template, according to some implementations.

In step 310, the process 300 includes applying one or more tolerances within the generated CAD assembly object, according to some implementations. In some implementations, the values of the first CAD assembly object include soft values that accommodate for manufacturing limitations via tolerances. In some implementations, the CAD model engine 130 is configured to determine one or more tolerance values for one or more attributes of the solid body CAD object based on the attributes of the CAD template object.

In step 312, the process 300 includes generating a second CAD assembly object, according to some implementations. In some implementations, the values of the attributes of the second CAD assembly object are fixed values. In some implementations, the CAD model engine 130 is configured to create an analysis-type solid body CAD assembly object. The analysis-type solid body CAD assembly object may have strict or fixed values that facilitate analysis and simulation of the solid body CAD assembly object within a CAD analysis environment. In some implementations, the analysis-type solid body CAD assembly object includes fully constrained motion and/or mesh definitions for a finite element analysis. In some implementations, the analysis-type solid body CAD assembly object includes attributes for one or more boundary conditions and/or loading conditions based on one or more attributes of the CAD template object.

In step 314, the process 300 includes applying the second CAD model to a finite element analysis environment, according to some implementations. In some implementations, step 314 includes applying the second CAD assembly object within a CAD analysis environment. In some implementations, the CAD model manager 132 may apply a solid body CAD object to one or more CAD analysis tools (e.g., finite element analysis).

In step 316, the process 300 includes presenting the CAD analysis result, according to some implementations. In some implementations, the CAD model manager 132 is configured to return analysis results to the GUI engine 122. The GUI engine 122 may present the results via one or more screens presented on a display device of the user interface 108.

Referring now to FIG. 4, a GUI 400 is configured to present screen 402. The GUI 400 includes a setpoint panel 404, a sketch panel 406, a check panel 408, a rules panel 410, an error panel 412, and an export panel 414, according to some implementations.

In some implementations, the setpoint panel 404 displays one or more adjustable attributes 418. In some implementations, the setpoints panel 404 includes a setpoint data table 416 that is configured to tabulate a set of adjustable attributes 418 and a set of setpoint values (e.g., operation values, current values, etc.) shown as adjustable attribute values 420. In screen 402, the setpoint data table 416 includes adjustable attribute XX, adjustable attribute YY, and adjustable attribute ZZ. The adjustable attribute value 420 of the adjustable attribute XX is 2, the adjustable attribute value 420 of the adjustable attribute YY is 3, and the adjustable attribute value 420 of the adjustable attribute ZZ is 10. In some implementations, the values of the adjustable attributes 418 include numerical values, textual values (e.g., A, B, C), percentages, binary cyphers, Boolean cyphers, symbols (e.g., squares, triangles, greek symbols, etc.), or other data types. For example, the adjustable attribute XX may be a percentage value between 0% and 100%. In some implementations, the setpoint data table 416 includes an additional column for the engineering units (e.g., inch, centimeter, percentage, volt, density, inch², meter³, kilowatt-hour, gram, meters/second, meters/second squared, pound-force, slug, etc.) of the adjustable attribute value 420. In some implementations, the fields (e.g., cells, containers, boxes, etc.) of the setpoint data table 416 may include dropdown options, sliders, scroll bars, or other interactive field options. For example, a user may interact with the interactive field 422, and, responsive to the interaction the GUI engine 122 may present a dropdown list of user selectable options (e.g., 1.3, 9, 1000, etc.). In some implementations, one or more of the adjustable attribute values 420 are entered or selected via an interactive field 422.

In some implementations, the sketch panel 406 includes a depiction of the CAD template object based on the setpoint values of the adjustable attributes (e.g., adjustable attribute values 420). The sketch panel 406 may include a geometry preview 424 including a depiction regarding the geometry of the CAD template object based on the adjustable attribute values 420. In some implementations, the geometry preview 424 includes a skeleton diagram 426 (e.g., sketch, line diagram, kinematic diagram, joint map, vector diagram, kinematic scheme, etc.) and rulers 428 that dimension the space of the geometry preview 424. In the skeleton diagram 426, the dashed lines and endpoint shapes are illustrate a color scheme where short dashes are blue, medium dashes are light blue, long dashes are green, and solid lines are red. In some implementations, the circular endpoints are blue, the square endpoints are red, the diamond endpoints are green, and the triangular endpoints are light blue. In some implementations, the skeleton diagram 426 is configured to distinguish the rigid members via a color scheme. In some implementations, the geometry preview 424 may include a depiction of the CAD template object within a first reference plane (e.g., an X-Y plane of a cartesian coordinate system), a second reference plane (e.g., a X-Z plane of a cartesian coordinate system), and/or a third reference plane (e.g., a Y-Z plane of a cartesian coordinate system).

In some implementations, the rules panel 410 includes a rules table 430. The rules table 430 can tabulate a set of rules 432. In screen 402, the set of rules 432 includes rule R1 and rule R2, according to some implementations. The rule R1 has a definition of AA<ZZ and the rule R2 has a definition of BB<YY. The rules 432 may include one or more logical test conditions (e.g., greater than, less than, equal to), according to some implementations. In some implementations, the set of rules 432 are based on one or more safety regulations, constraints, and/or criteria. For example, a rule may be based on a logical test involving a mechanical performance metric, such as a lift capacity, an overall dimension (length, width, and/or height), an extension height, a maximum scissor angle, a peak stress, or a factor of safety. In some implementations, the rules in the rules table 430 are managed by the rules engine 126.

In some implementations, the check panel 408 includes a check table 440. The check table 440 can tabulate a set of dependent attributes 442. In screen 402, the set of dependent attributes 442 includes dependent attribute AA and dependent attribute BB, according to some implementations. The dependent attribute AA is defined as the sum of the adjustable attribute XX and the adjustable attribute YY (e.g., AA=XX+YY). The dependent attribute BB is defined as the product of the adjustable attribute ZZ and a scalar value 0.3 (e.g., BB=ZZ*0.3). The dependent attribute values 443 are based on an evaluation of the definition (e.g., XX+YY, ZZ*0.3, etc.) of the dependent attribute 442. The dependent attributes of the set of dependent attributes 442 may be dependent on one or more adjustable attributes of the set of adjustable attributes 418, and/or one or more dependent attributes of the set of dependent attributes 442, and/or one or more scalar values (e.g., conversion factors). In some implementations, the check panel 408 is managed by the rules engine 126.

In some implementations, the check panel 408 includes one or more graphic representations (e.g., plots, scatter plots, bar graphs, etc.) shown as a chart 444 and a chart 446. In some implementations, the chart 444 is a plot exhibiting a set of values over a range of related values. In screen 402, the chart 444 illustrates stresses (e.g., maximum bending stress, minimum bending stress, etc.) over a range of angular values corresponding to a range of motion of the CAD template object, according to some implementations. In screen 402, chart 446 illustrates the loading experienced by an actuator over a range of motion of the CAD template object (e.g., an opening angle, a length of extension, a rotational speed, etc.).

In some implementations, the chart 446 exhibits a plot of values over related values based on perturbations to one or more adjustable attributes 418. For example, the chart 446 may exhibit a first data point based on the adjustable attribute values 420, a second data point based on a value of an adjustable attribute combined with a first perturbation value (e.g., setpoint value+0.2 inch, setpoint value−0.2 inch, setpoint value*2, setpoint value÷2, etc.), and a third data point based on a value of an adjustable attribute combined with a second perturbation value opposite the first perturbation value. For example, if the first perturbation value is based on the setpoint value+2, the second perturbation value can be based on the setpoint value−2 inch. In this example, the chart 446 may plot the first value, the second value, and the third value against the setpoint value combined with the perturbation values (e.g., [−2, 0, +2] in this example). For example, the chart 446 may track perturbations made to an adjustable attribute value 420 (e.g., a historical analysis), or may generate a preview based on the adjustable attribute value (e.g., a forecasting analysis). In some implementations, the chart 446 is configured to display multiple perturbation values that cover a range of possible values of an adjustable attribute 418. Advantageously, the chart 446 can enable an automatic presentation of study of the values of the adjustable attributes 418 and provide valuable insight that can aid in developing the set of adjustable attribute values 420.

In some implementations, the error panel 412 includes an error table 450. The error table 450 can tabulate a set of status indicators 452. In some implementations, the set of status indicators 452 includes one or more no-error indicators 454 and one or more error indicators 456. The no-error indicator 454 is configured to convey an indication of compliance to one or more rules of the set of rules 432 based on the adjustable attribute values 420. In screen 402, the error table 450 includes a no-error indicator 454 displaying a textual message “OK” in response to a determination that the criteria of the associated rule (e.g., rule R1) is satisfied, according to some implementations. In screen 402, the error table 450 includes an error indicator 456 displaying a textual message “ERROR” in response to a determination that the criteria of the associated rule (e.g., rule R2) is not satisfied. It is contemplated that other error indications and no-error indications may be utilized to indicate compliance or noncompliance with one or more rules of the set of rules 432. For example, the no-error indicator 454 and error indicator 456 may display in different colors (e.g., green, red, orange, yellow, etc.), display a binary value or a Boolean value (e.g., “1” or “0”, “good” or “bad”, “yes” or “no”, “go” or “no-go”, “comply” or “no comply”, “pass” or “fail”, etc.), generate a popup that overlays at least a portion of the content of the screen 402, generate an auditory alert, flash or blink some or all of the screen content of the screen 402, etc. responsive to the determination whether the adjustable attribute values 420 comply with the one or more rules of the set of rules 432.

In some implementations, the export panel 414 includes an export status table 460, and a user interactive object (e.g., button, toggle, user interactive display object, interactive trigger, etc.), shown as export button 462. In some implementations, the export status table 460 can tabulate export status information. For example, the export status table 460 may display a message 464 regarding whether applying the adjustable attribute values 420 to a solid body CAD model is permitted. In some implementations, message 464 may be or include a textual message “Locked-Fix Error(s)” or other indications regarding the export status (e.g., a smiley face or a frowning face, green color or a red color, etc.). In some implementations, the export status message 464 is based on a determination whether the set of error status indicators 452 include an indication of noncompliance. For example, the compliance engine 128 may determine whether the set of error status indicators 452 includes a status indicator that is indicative of noncompliance (e.g., the error indicator 456, an “ERROR” message, a binary cipher, a Boolean cipher, etc.), and, based on a determination that the set of error status indicators 452 includes an indicator indicative of noncompliance (e.g., an error indicator 456), instruct the GUI engine 122 to present an indication of disabled export functionality. For example, the indicator indicative of noncompliance may include a locked lock icon 466 or other indications of the disabled export functionality. In some implementations, the compliance engine 128, based on a determination that the set of error status indicators 452 does not include an indicator indicative of noncompliance (e.g., does not include an error indicator 456), presents an indication of an enabled export functionality. For example, the indication of an enabled export functionality may be an unlocked lock icon (e.g., that replaces the locked lock icon 466).

In some implementations, the compliance engine 128 instructs the CAD model engine 130 to apply the adjustable attribute values 420 to a solid body CAD object based on a determination that the set of error status indicators 452 does not include an indicator indicative of noncompliance based on the one or more rules of the set of rules 432. In some implementations, the compliance engine 128 can toggle between (i) an automatic mode, where the compliance engine 128 automatically instructs the CAD model engine 130 to apply the adjustable attribute setpoint values 420 to a solid body CAD object based on a determination that the set of error status indicators 452 does not include an indicator indicative of noncompliance to one or more rules of the set of rules 432, and (ii) an on-demand mode, where the compliance engine 128 instructs the CAD model engine 130 to apply the adjustable attribute setpoint values 420 to a solid body CAD object in response to one or both of: (a) a receipt of an indication of a user input regarding instructions to export the set of adjustable attribute values 420, and (b) a determination that the set of error status indicators 452 does not include an indicator indicative of noncompliance to one or more rules of the set of rules 432. In some implementations, the compliance engine 128 prevents the CAD model engine 130 from applying one or more adjustable attribute values 420 to a solid body CAD object based on a determination that the set of error status indicators 452 includes an indicator indicative of noncompliance to one or more rules of the set of rules 432. In some implementations, the compliance engine 128 is configured to prevent a script from running while the set of error status indicators 452 includes an indicator indicative of noncompliance (e.g., an error indicator 456).

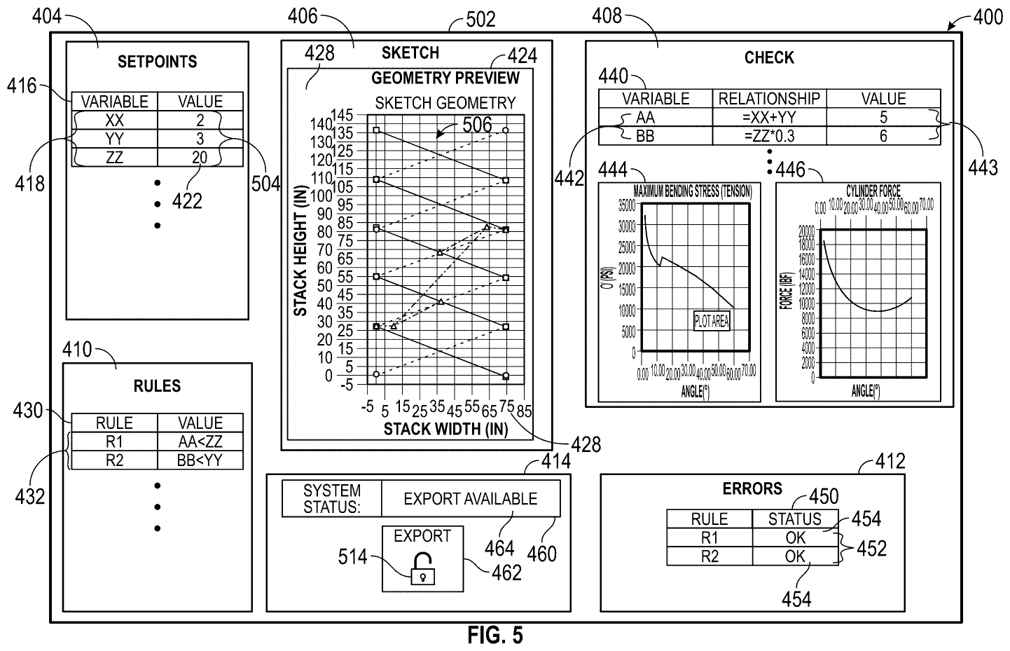

Referring now to FIG. 5, the GUI 400 is presenting a screen 502 after presenting the screen 402, according to some implementations. In screen 502, the setpoint data table 416 displays the adjustable attribute values 504. The value of the adjustable attribute ZZ is 20 (in FIG. 4 the value of the adjustable attribute ZZ is 10). The sketch panel 406, the check panel 408, the error panel 412, and the export panel 414 are updated and reflect the set of adjustable attribute values 504. For example, the check panel 408 displays that the value of the dependent attribute BB is 6. The sketch panel 406 includes a skeleton diagram 506 based on the adjustable attribute values 504. The errors panel 412 displays a no-error indicator 454 for rule R2. The export panel 414 displays an indication that export is permitted. In screen 502, the message 464 is changed to “Export Available”. The export button 462 displays an unlocked lock icon 514.

Although the setpoint panel 404, the sketch panel 406, the check panel 408, the rules panel 410, the error panel 412, and the export panel 414, are illustrated as being displayed within one screen (e.g., screen 402, screen 502), it is contemplated that some or all of the GUI 400 may span across spreadsheets, workbooks, webpages, windows, popup windows, or combinations thereof. In some implementations, the GUI 400 is presented in a format that may is navigable by a user (e.g., pan, scroll, zoom, cycle). In some implementations, the setpoint panel 404, the sketch panel 406, the check panel 408, the rules panel 410, the error panel 412, and the export panel 414 are pages in a digital packet (e.g., spreadsheets in a workbook), popup windows, or other interface tools that are configured to organize and present a GUI on a display having limited dimensions.

In some implementations, the setpoint panel 404, the sketch panel 406, the check panel 408, the rules panel 410, the error panel 412, and the export panel 414 are displayed in an integrated format. For example, the contents of the setpoint panel 404 may be combined with some or all the contents of the check panel 408, and the combined contents may be displayed in a combined panel of the GUI 400.

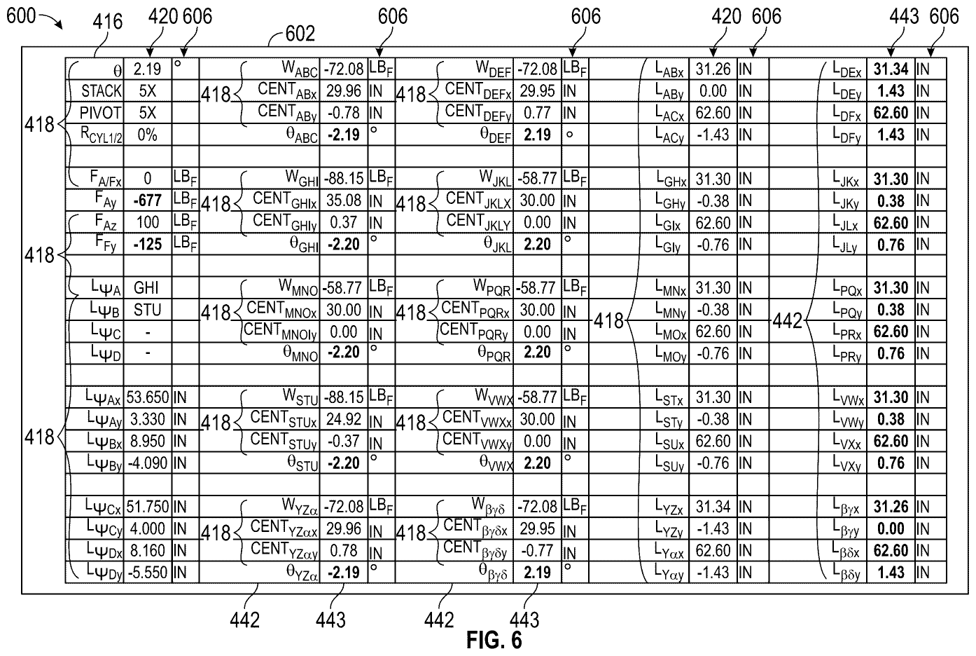

Referring now to FIGS. 6-8, a GUI 600 is configured to present a screen 602. The screen 602 includes adjustable attributes 418 and dependent attributes 442. The screen 602 is configured to display engineering units 606 of the values of the adjustable attributes 418 and the values of the dependent attributes 442. In FIGS. 6-16, the CAD template object is of a scissor stack assembly (e.g., for a scissor lift machine). In some implementations, the CAD template object manager 118 is configured to generate adjustable attributes 418 and dependent attributes based on the linkage diagram 700. The sketch engine 124 may generate the linkage diagram 700. In screen 602, the adjustable attributes 418 include an angle, shown as “θ”; a stack pattern count, shown as “Stack”; a pivot axis, shown as “Pivot”; a loading ratio between a first actuator and a second actuator, shown as “r_{CYL1/2}”, a point load applied to a point, shown as “F_{A/FX}”; a force applied to a point, shown as “F_{z}”; actuator mounting points, shown as “L_{ΨA}”, “L_{ΨB}”, “L_{ΨC}”, and “L_{ΨD}”; and other adjustable attributes for weights (e.g., “W” followed by a subscripted character(s)), heights (e.g., “h” followed by a subscripted character(s)), angles (e.g., “θ” followed by a subscripted character(s)), center locations (e.g., “cent” followed by a subscripted character(s)), and/or lengths (e.g., “L” followed by a subscripted character(s)).

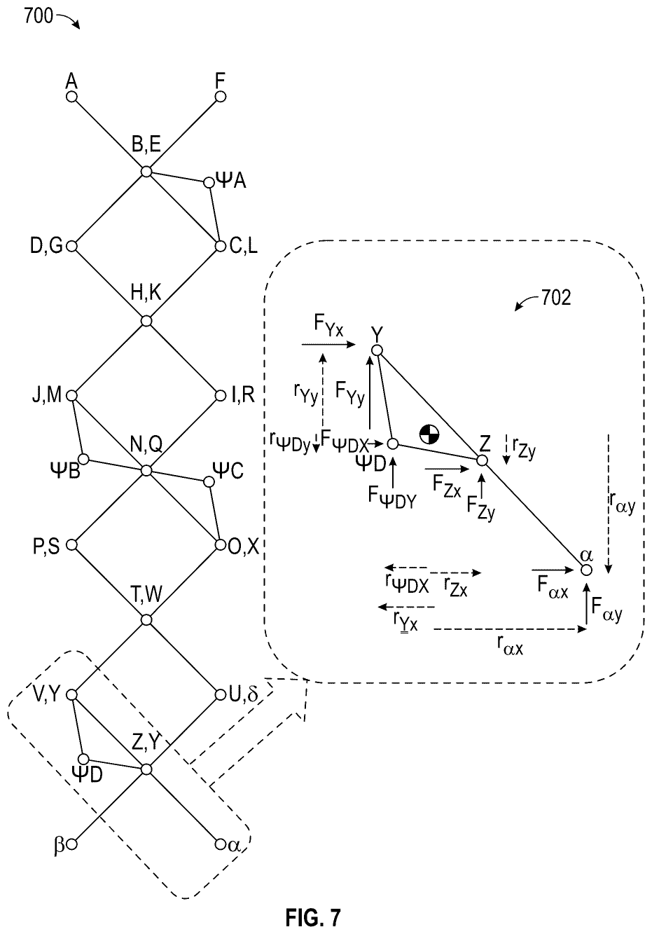

Referring to FIG. 7, the full scissor stack assembly includes members “ABC”, “DEF”, “GHI”, “JKL”, “MNO”, “POR”, “STU”, “VWX”, “YZα”, and “βγδ”, according to some implementations. In FIG. 7, one or more revolute joints (e.g., pins) are shown, according to some implementations. For example, the point “B, I”, may be a pinned relationship between member “ABC” and member “ABC” at point “B” of member “ABC” and point “E” of member “DEF.” As another example, point “D, G” may be a pinned relationship between member “DEI” and member “GHI” at point “D” of member “DEF” and point “G” of member “GHI”, according to some implementations. In some implementations, the linkage diagram 700 includes members that illustrate one or more mount plates bonded to one or more members of the linkage diagram 700. For example, the member “ABC” includes an additional pin signified by “ΨA”, the member “MNO” includes an additional pin “ΨB” and an additional pin “ΨC”, and the member “YZα” includes an additional pin “ΨD”. In some implementations, the additional pin(s) are provided in pairs with a linear actuator coupled between the additional pins. For example, pin “ΨA” and pin “ΨB” are a pair associated with a first actuator (e.g., hydraulic actuator), and pin “ΨC” and pin “ΨD” are a pair associated with a second actuator. In some implementations, the first actuator and/or the second actuator are assumed to be a two-force member. In some implementations, the adjustable attributes 418 facilitate modifying the additional pin locations and the quantity of additional pin locations.

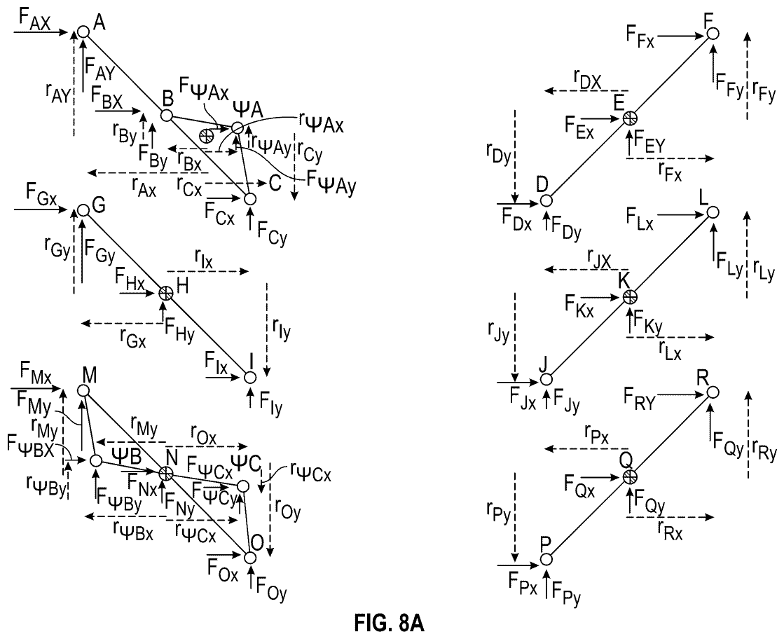

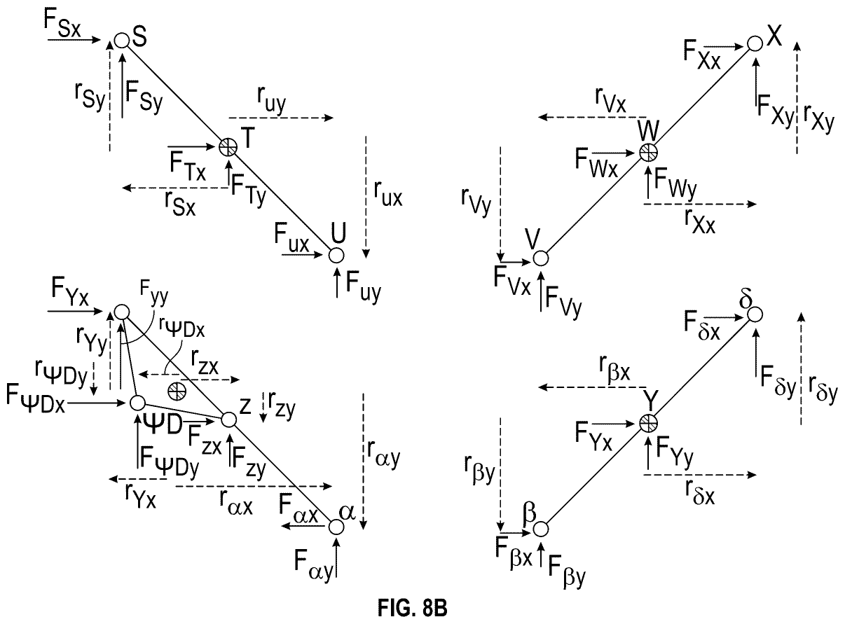

Referring now to FIGS. 7 and 8A-8B, the sketch engine 124 is configured to generate one or more kinematic diagrams, shown as free body diagram 702 and free body diagram 800. In some implementations, the CAD template object manager 118 is configured to generate one or more dependent attributes 442 based on a rigid body force analysis of one or more members of the CAD template object. For example, the adjustable attributes 418 and/or the dependent attributes 442 of the CAD template object may include one or more loads applied to one or more members of the linkage diagram 700. In the free body diagram 702 and free body diagram 800, each “F” represents a force, and each “r” is a moment arm relative to the center of mass, according to some implementations. The arrows shown with arrow heads in the general vicinity of a point correspond to a force applied to the point. For example, in free body diagram 702, point a of the member YZα is the point at which the forces r_{ay}, Fₐₓ, F_{ay}, and rₐₓ are applied to the member YZα. As another example, in free body diagram 702, point Z of the member YZα is the point at which the forces r_{zy}, F_{Zx}, F_{Zy}, and r_{Zx} are applied to the member YZα. The directions of the arrows shown in the free body diagram 702 and the free body diagram 800 indicate the relative directions the forces are applied to the point (e.g., in a x-y-z component).

In some implementations, the CAD template object manager 118 generates one or more dependent attributes 442 based on a determination of static equilibrium. For example, the one or more dependent attributes 442 may be based on a sum of forces and a sum of moments. For example, the rules engine 126 may include one or more relationships between one or more attributes of the CAD template object based on Equation 1, Equation 2, Equation 3, and Equation 4, shown below

$$\sum {F}_{x} = 0 \qquad [ 1 ]$$

$$\sum {F}_{y} = 0 \qquad [ 2 ]$$

$$\sum {F}_{z} = 0 \qquad [ 3 ]$$

$$\sum {M}_{Point} = 0 \qquad [ 4 ]$$

where “Fₓ” is the forces in an x-direction, “F_{y}” is the forces in a y-direction, “F_{z}” is the forces in a z-direction, and “Mₚₒᵢₙₜ” are the moments with respect to a point in space.

In some implementations, the CAD template object manager 118 generates one or more dependent attributes based on an a static force equilibrium with respect to the actuator(s). For example, the CAD template object manager 118 may generate one or more dependent attributes based on Equation 5 and Equation 6, shown below

$$tan ( {θ}_{A 1} ) * {F}_{Ψ Ax} - {F}_{Ψ Ay} = 0 \qquad [ 5 ]$$

$$tan ( {θ}_{A 2} ) * {F}_{Ψ Cx} - {F}_{Ψ Cy} = 0 \qquad [ 6 ]$$

where θ_{Λ} is the angle of the respective actuator and the other variables are as defined previously. In some implementations, an adjustable attribute 418 may be a ratio between a pair of actuators. For example, the CAD template object manager 118 may determine one or more attributes based on Equation 7, shown below

$$n * {F}_{Ψ A} - {F}_{Ψ C} = 0 \qquad [ 7 ]$$

where n is a ratio of actuator performance. For example, if n is zero, the other actuator will be determined a zero-force member, effectively removing it from the system. In some implementations, a dependent attribute may be a cross sectional area of a portion of the CAD template object. In some implementations, a dependent attribute may be a moment of inertia. For example, a dependent attribute may be based on Equation 8, shown below

$$I = [ \frac{1}{12} ( w ) {( h )}^{3} ] - [ \frac{1}{12} ( w - 2 t ) {( h - 2 t )}^{3} ] - \qquad [ 8 ]$$

$$[ {( 2 r )}^{2} {( \frac{h}{2} - r )}^{2} ] + [ π {{r}^{2} ( \frac{h}{2} - r )}^{2} ] - [ {π ( r - t )}^{2} {( \frac{h}{2} - r )}^{2} ]$$

where I is the cross-sectional moment of inertia about the neutral axis (assumed to be the centroid). In some implementations, a dependent attribute may be a bending stress. For example, a dependent attribute may be based on Equation 9, shown below

$$σ = \frac{M ( h / 2 )}{I} + \frac{P}{A} \qquad [ 9 ]$$

where σ is direct stress, M is bending moment, and P is axial force.

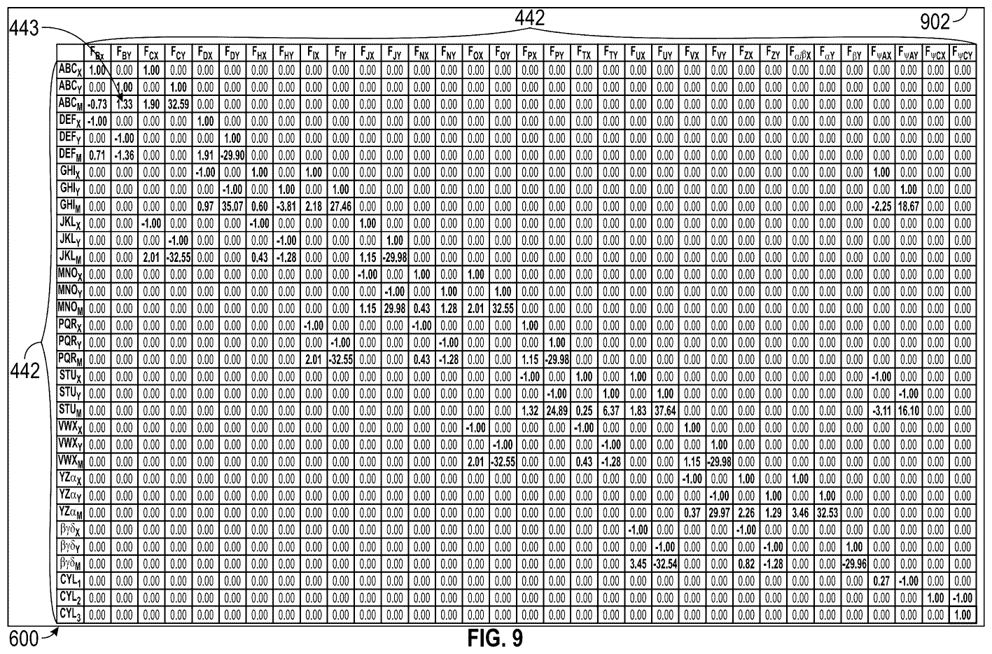

Referring to FIG. 9, the GUI 600 is configured to present a screen 902. The screen 902 includes dependent attributes 442 in a matrix structure. The dependent attribute values 443 include conditional formatting, according to some implementations. For example, positive values may be displayed in green while negative values may be displayed in purple.

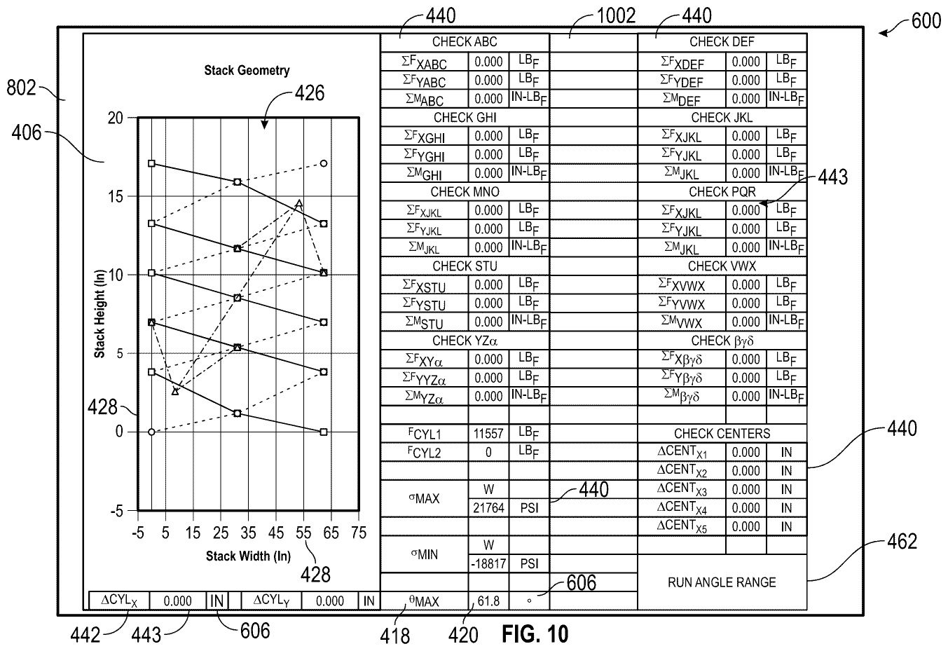

Referring to FIG. 10, the GUI 600 is configured to present a screen 1002. The screen 1002 includes an adjustable attribute 418, dependent attributes 442, an export button 462, a skeleton diagram 426 and check tables 440.

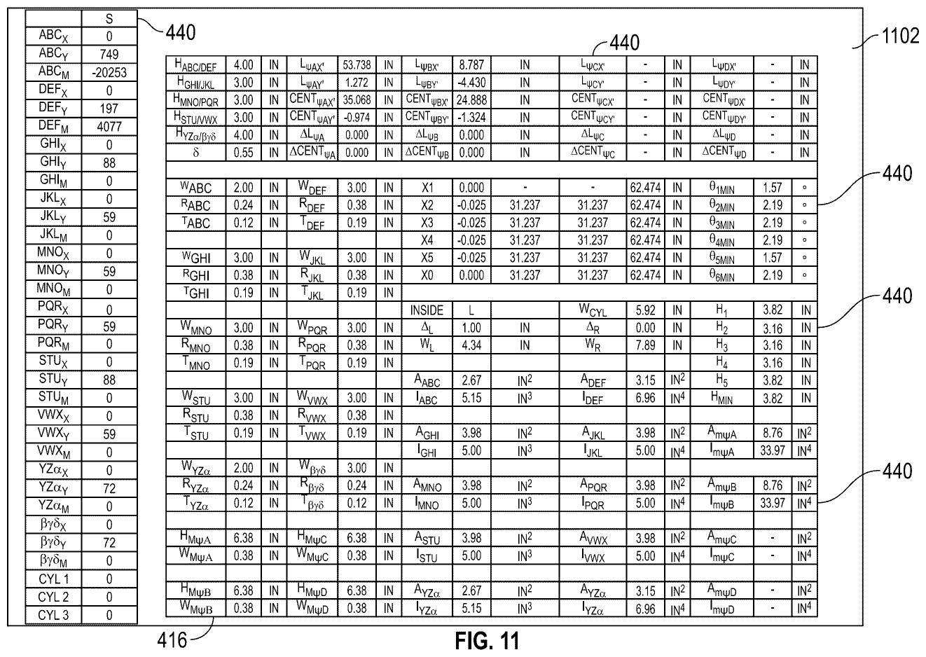

Referring to FIG. 11, the GUI 600 is configured to present a screen 1102. The screen 1102 includes check tables 440 and a setpoint data table 416.

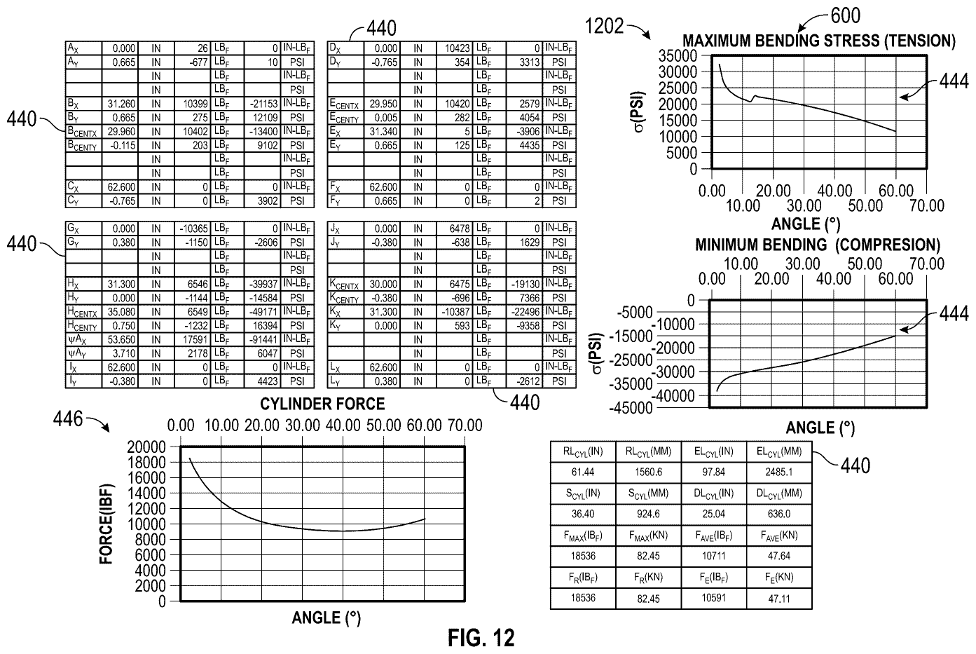

Referring to FIG. 12, the GUI 600 is configured to present a screen 1202. The screen 1202 includes check tables 440, charts 444, and chart 446.

Referring now to FIG. 13, the GUI 600 is configured to present a screen 1302. The screen 1002 includes the sketch panel 406 having a skeleton diagram 1104 based on the adjustable attribute values 420.

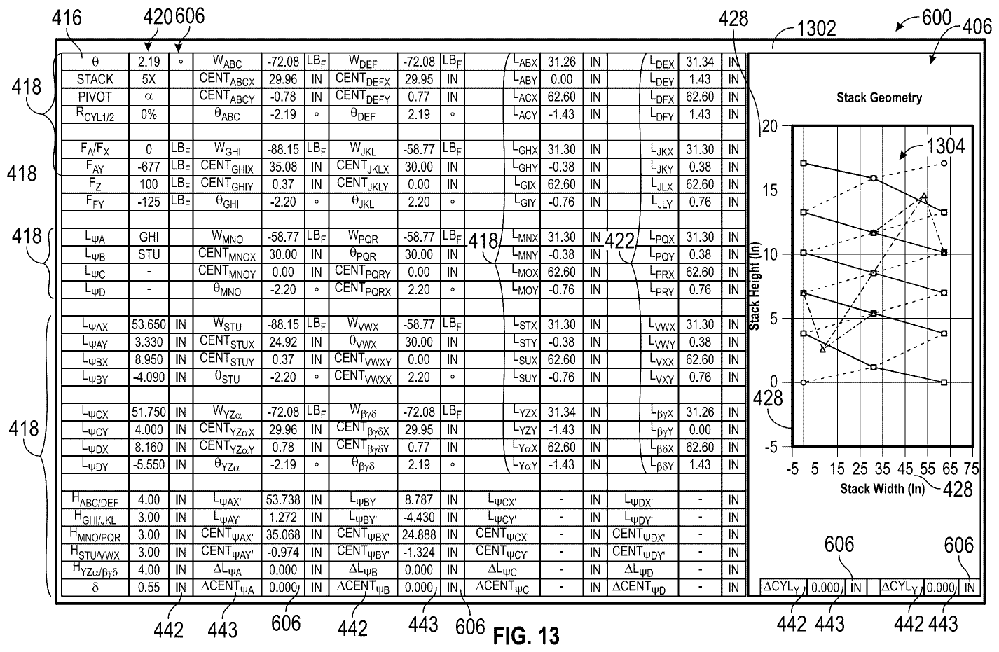

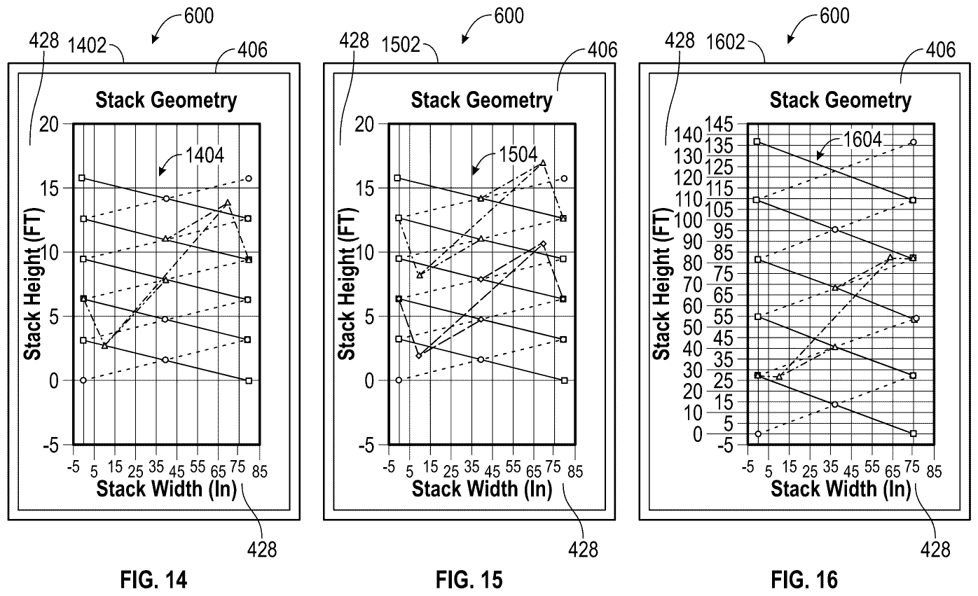

Referring to FIG. 14, the GUI 600 is configured to present a screen 1402. The screen 1402 includes the sketch panel 406 featuring a skeleton diagram 1404 based on a set of adjustable attributes (e.g., adjustable attributes 418).

Referring to FIG. 15, the GUI 600 is configured to present a screen 1502. The screen 1502 includes the sketch panel 406 featuring a skeleton diagram 1504 based on adjustable attributes (e.g., adjustable attributes 418).

Referring to FIG. 16, the GUI 600 is configured to present a screen 1602. The screen 1602 includes the sketch panel 406 featuring a skeleton diagram 1604 based on adjustable attributes (e.g., adjustable attributes 418).

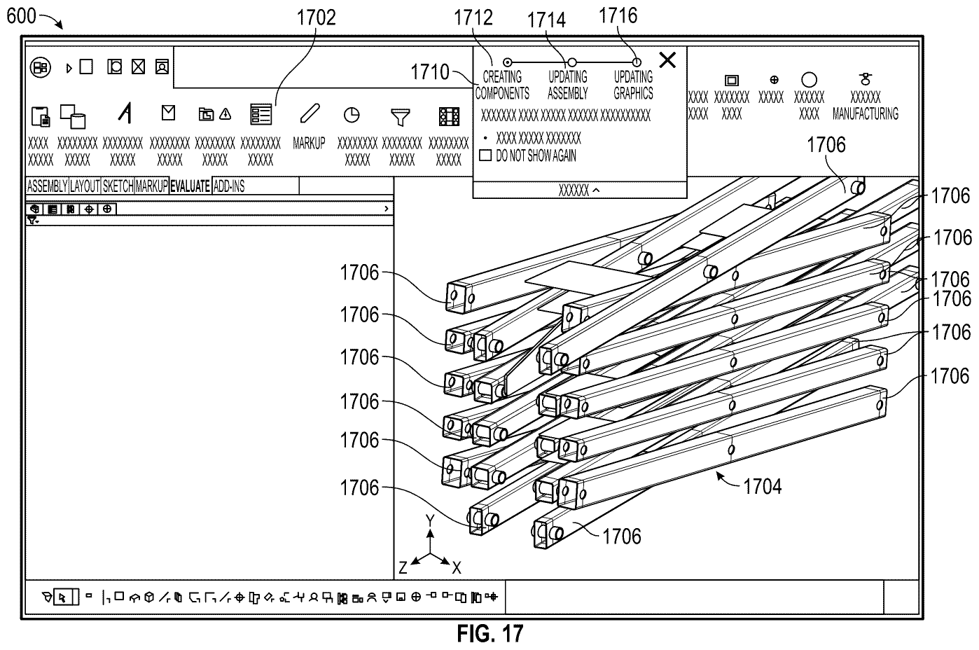

Referring now to FIG. 17, the GUI 600 is configured to present a screen 1702. The screen 1702 includes a solid body CAD assembly object 1704 based on the adjustable attribute values 420, according to some implementations. The solid body CAD assembly object 1704 includes solid body CAD objects 1706. The solid body CAD objects 1706 are based on the adjustable attribute values 420, according to some implementations. In some implementations, screen 1702 includes a popup window 1710 including status information regarding the application of the adjustable attribute values (e.g., the adjustable attribute values 420). For example, the popup window 1710 may include a “creating components” message 1712, an “updating assembly” message 1714, and a “updating graphics” message 1716.

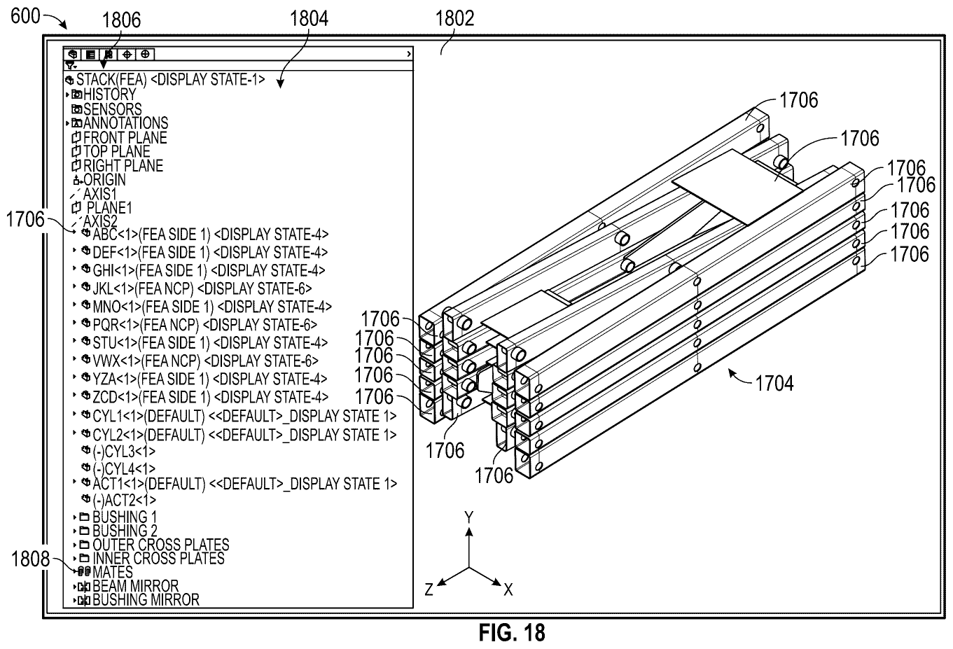

Referring now to FIG. 18, the GUI 600 is configured to present a screen 1802. The screen 1802 includes the solid body CAD assembly object 1704 and a navigation panel 1804. The navigation panel 1804 includes a list 1806 (e.g., tree, cascaded tree, multi-level list, etc.) of the attributes of the solid body CAD assembly object 1704. The list 1806 includes one or more mates 1808 applied to the solid body CAD assembly object 1704 based on the adjustable attributes 418, according to some implementations. In some implementations, the list 1806 includes one or more tolerances for one or more attributes of the solid body CAD assembly object based on the adjustable attributes 418.

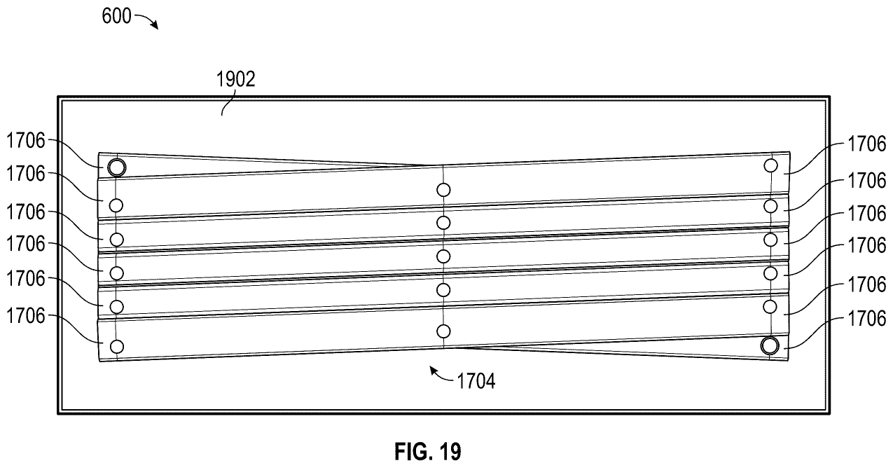

Referring now to FIG. 19, the GUI 600 is configured to present a screen 1902. The screen 1902 includes a side view of the solid body CAD assembly object 1704.

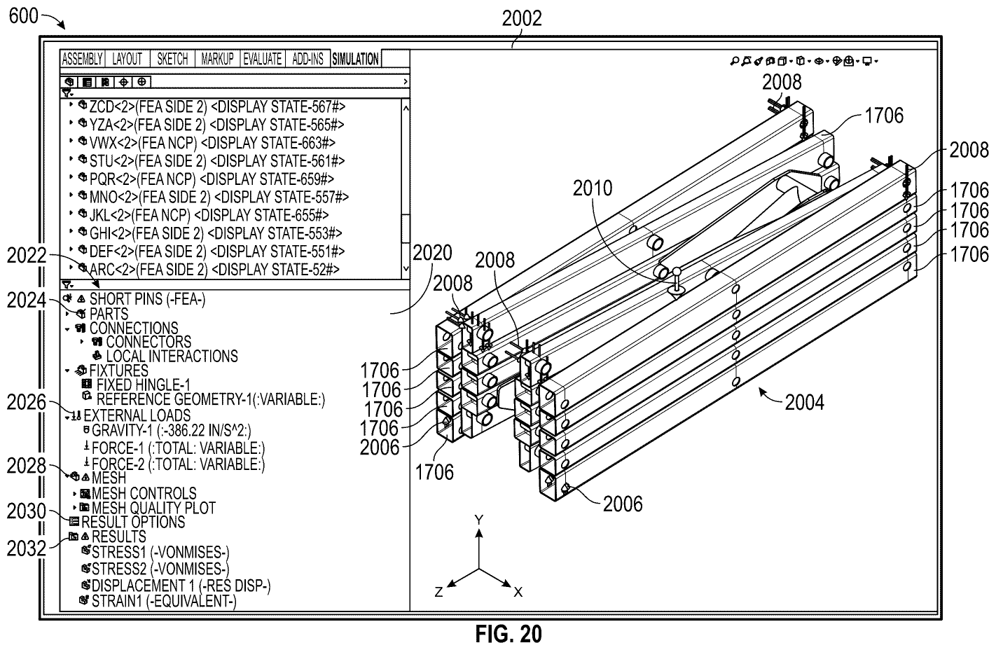

Referring now to FIG. 20, the GUI 600 is configured to present a screen 2002. The screen 2002 includes a CAD assembly object 2004. In some implementations, the solid body CAD assembly object 2004 may include some or all of the features and functionality of the solid body CAD assembly object 1704. In some implementations, the solid body CAD assembly object 2004 may include some or all of the features and functions of the solid body CAD assembly object 2004. The solid body CAD assembly object 2004 may be or include a copy of the solid body CAD object 1704, according to some implementations. In some implementations, the solid body CAD object 2004 includes the same attributes as the solid body CAD assembly object 1704. The attributes of the solid body CAD assembly object 2004 may have fixed attribute values (e.g., no tolerances) and constrained relative motion between the constituent solid body CAD objects 1706 of the solid body CAD assembly object 2004. In some implementations, the screen 2002 is configured to display one or more indications of a simulated load applied to the solid body CAD object 2004. For example, the screen 2002 includes reaction force arrows 2006 and applied load arrows 2008. The screen 2002 includes the navigation panel 2020 and a list of CAD analysis attributes 2022. The list of CAD analysis attributes 2022 includes the solid body CAD assembly attributes 2024, external load attributes 2026, mesh attributes 2028, analysis result settings 2030, and analysis result attributes 2032.

According to various implementations, the CAD systems and methods described herein provide improvements over the current systems and methods by preventing generation of a solid body CAD model based on parameter values that do not adhere to design constraints and criteria, and by automatically generating one or more solid body CAD models based on a set of parameter values that adhere to design constraints and criteria. The technical solutions described herein provide many technical benefits including: 1) reducing costs throughout the design and manufacturing process, 2) decreasing wasted computing resources, 3) reducing time spent on data entry and data manipulation, 4) reducing the production and storage of nonviable CAD models, 5) providing valuable insights into design functionality (e.g., motion, assembly behavior, loading, etc.) early in the design process, and 6) reducing tolerance stack up and similar errors within a solid body CAD model.

As utilized herein with respect to numerical ranges, the terms “approximately,” “about,” “substantially,” and similar terms generally mean +/−10% of the disclosed values. When the terms “approximately,” “about,” “substantially,” and similar terms are applied to a structural feature (e.g., to describe its shape, size, orientation, direction, etc.), these terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as utilized herein to describe various implementations, are intended to indicate that such implementations are possible examples, representations, or illustrations of possible implementations (and such terms are not intended to connote that such implementations are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the FIGURES. It should be noted that the orientation of various elements may differ according to other exemplary implementations, and that such variations are intended to be encompassed by the present disclosure.

The hardware and data processing components used to implement the various processes, operations, illustrative logics, logical blocks, modules and circuits described in connection with the implementations disclosed herein may be implemented or performed with a general purpose single- or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, or, any conventional processor, controller, or microcontroller. A processor may also be implemented as a combination of computing devices, such as a combination of a DSP and a microprocessor, multiple microprocessors, one or more microprocessors in conjunction with a DSP core, or any other such configuration. In some implementations, particular processes and methods may be performed by circuitry that is specific to a given function. The memory (e.g., memory, memory unit, storage device) may include one or more devices (e.g., RAM, ROM, Flash memory, hard disk storage) for storing data and/or computer code for completing or facilitating the various processes, layers, and modules described in the present disclosure. The memory may be or include volatile memory or non-volatile memory, and may include database components, object code components, script components, or any other type of information structure for supporting the various activities and information structures described in the present disclosure. According to an exemplary implementation, the memory is communicably connected to the processor via a processing circuit and includes computer code for executing (e.g., by the processing circuit or the processor) the one or more processes described herein.

The present disclosure contemplates methods, system and program products on any machine-readable media for accomplishing various operations. The implementations of the present disclosure may be implemented using existing computer processors, or by a special purpose computer processor for an appropriate system, incorporated for this or any other purpose, or by a hardwired system. Implementations within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data that cause a general purpose computer, special purpose computer, or special purpose processing machine to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the construction and arrangement of the CAD system 100 as shown in the various exemplary implementations is illustrative only. Additionally, any element disclosed in one implementation may be incorporated or utilized with any other implementation disclosed herein. Although only one example of an element from one implementation that can be incorporated or utilized in another implementation has been described above, it should be appreciated that other elements of the various implementations may be incorporated or utilized with any of the other implementations disclosed herein.

What is claimed is:

1. A computer-implemented method for computer aided design (CAD), comprising:
maintaining a CAD template object comprising a first plurality of attributes and a second plurality of attributes, wherein the first plurality of attributes comprises adjustable attributes, and the second plurality of attributes comprises dependent attributes;
presenting, via a user interface, a graphic user interface (GUI) regarding the first plurality of attributes, the second plurality of attributes, and a sketch regarding the CAD template object;
receiving, via the user interface, an input regarding a setpoint value for an adjustable attribute of the first plurality of attributes;
applying the setpoint value to the adjustable attribute of the first plurality of attributes;
updating the second plurality of attributes based on the setpoint value applied to the adjustable attribute of the first plurality of attributes;
presenting, via the user interface, an updated sketch of the CAD template object based on the first plurality of attributes and the second plurality of attributes;
determining whether the setpoint value for the adjustable attribute is valid by comparing a value of an attribute of the second plurality of attributes to a threshold value; and
subsequent to determining whether the setpoint value of the adjustable attribute is valid, generating, without additional user input, a plurality of solid body CAD objects based on the first plurality of attributes and the second plurality of attributes.

2. The computer-implemented method of claim 1, further comprising subsequent to determining that the setpoint value of the adjustable attribute is valid:
assigning a unique tag to each of the plurality of solid body CAD objects, wherein the unique tag is based on the first plurality of attributes and the second plurality of attributes;
generating a solid body CAD assembly object of the plurality of solid body CAD objects; and
automatically applying, based on the unique tags, a plurality of geometric relationships between the plurality of solid body CAD objects.

3. The computer-implemented method of claim 1, further comprising subsequent to determining that the setpoint value is valid:
generating a first solid body CAD assembly object and a second solid body CAD assembly object, wherein the values of the attributes of the first solid body CAD assembly object includes tolerances, and wherein the values of the attributes of the second CAD assembly object are fixed values.

4. The computer-implemented method of claim 3, further comprising applying the second CAD assembly object to a finite element analysis.

5. The computer-implemented method of claim 1, further comprising: based on a determination that the setpoint value of the adjustable attribute is not valid, preventing values of the second plurality of attributes from being applied to a CAD object.

6. The computer-implemented method of claim 1, further comprising:
based on a determination that the setpoint value of the adjustable attribute is not valid, presenting, via the user interface, an alert regarding the determination.

7. The computer-implemented method of claim 1, wherein the sketch comprises one or more rulers configured to dimension the sketch.

8. A non-transitory computer readable media having computer-executable instructions therein that, when executed by at least one processor, cause the at least one processor to perform operations for computer aided design (CAD), the operations comprising:
maintaining a CAD template object comprising a first plurality of attributes and a second plurality of attributes, wherein the first plurality of attributes comprises adjustable attributes, and the second plurality of attributes comprises dependent attributes;
presenting, via a user interface, a graphic user interface (GUI) regarding the first plurality of attributes, the second plurality of attributes, and a sketch regarding the CAD template object;
receiving, via the user interface, an input regarding a setpoint value for an adjustable attribute of the first plurality of attributes;
applying the setpoint value to the adjustable attribute of the first plurality of attributes;
updating the second plurality of attributes based on the setpoint value applied to the adjustable attribute of the first plurality of attributes;
presenting, via the user interface, an updated sketch of the CAD template object based on the first plurality of attributes and the second plurality of attributes;
determining whether the setpoint value for the adjustable attribute is valid by comparing a value of an attribute of the second plurality of attributes to a threshold value; and
subsequent to determining whether the setpoint value of the adjustable attribute is valid, generating, without additional user input, a plurality of solid body CAD objects based on the first plurality of attributes and the second plurality of attributes.

9. The non-transitory computer readable media of claim 8, further comprising: subsequent to determining whether the setpoint value of the adjustable attribute is valid:
assigning a unique tag to each of the plurality of solid body CAD objects, wherein the unique tag is based on the first plurality of attributes and the second plurality of attributes;
generating a solid body CAD assembly object of the plurality of solid body CAD objects; and
automatically applying, based on the unique tags, a plurality of geometric relationships between the plurality of solid body CAD objects.

10. The non-transitory computer readable media of claim 8, further comprising: subsequent to determining whether the setpoint value is valid:
generating a first solid body CAD assembly object and a second solid body CAD assembly object, wherein the values of the attributes of the first solid body CAD assembly object includes tolerances, and wherein the values of the attributes of the second CAD assembly object are fixed values.

11. The non-transitory computer readable media of claim 10, further comprising applying the second CAD assembly object to a finite element analysis.

12. The non-transitory computer readable media of claim 8, further comprising: based on a determination that the setpoint value of the adjustable attribute is not valid, preventing values of the second plurality of attributes from being applied to a CAD object.

13. The non-transitory computer readable media of claim 8, wherein the sketch comprises one or more rulers configured to dimension the sketch.

14. The non-transitory computer readable media of claim 8, further comprising:
based on a determination that the setpoint value of the adjustable attribute is not valid, presenting, via the user interface, an alert regarding the determination.

15. A system for computer aided design (CAD), comprising:
one or more memory devices storing instructions thereon that, when executed by one or more processors, cause the one or more processors to:
maintain a CAD template object comprising a first plurality of attributes and a second plurality of attributes, wherein the first plurality of attributes comprises adjustable attributes, and the second plurality of attributes comprises dependent attributes;
present, via a user interface, a graphic user interface (GUI) regarding the first plurality of attributes, the second plurality of attributes, and a sketch regarding the CAD template object;
receive, via the user interface, an input regarding a setpoint value for an adjustable attribute of the first plurality of attributes;
apply the setpoint value to the adjustable attribute of the first plurality of attributes;
update the second plurality of attributes based on the setpoint value applied to the adjustable attribute of the first plurality of attributes;
present, via the user interface, an updated sketch of the CAD template object based on the first plurality of attributes and the second plurality of attributes;
determine whether the setpoint value for the adjustable attribute is valid by comparing a value of an attribute of the second plurality of attributes to a threshold value; and
subsequent to determining whether the setpoint value of the adjustable attribute is valid, generate, without additional user input, a plurality of solid body CAD objects based on the first plurality of attributes and the second plurality of attributes.

16. The system of claim 15, wherein the instructions cause the one or more processors to:
subsequent to determining whether the setpoint value is valid:
assign a unique tag to each of the plurality of solid body CAD objects,
wherein the unique tag is based on the first plurality of attributes and the second plurality of attributes;
generate a solid body CAD assembly object of the plurality of solid body CAD objects; and
automatically apply, based on the unique tags, a plurality of geometric relationships between the plurality of solid body CAD objects.

17. The system of claim 15, wherein the instructions further cause the one or more processors to:
subsequent to determining whether the setpoint value is valid:
generate a first CAD assembly object and a second CAD assembly object of the plurality of CAD objects, wherein the values of the first CAD assembly object include soft values, and the values of the attributes of the second CAD assembly object are fixed values.

18. The system of claim 17, wherein the instructions further cause the one or more processors to:
apply the second cad assembly object to a finite element analysis.

19. The system of claim 15, wherein the instructions further cause the one or more processors to:
based on a determination that the setpoint value of the adjustable attribute is not valid:
prevent values of the second plurality of attributes from being applied to a CAD object.

20. The system of claim 15, wherein the instructions further cause the one or more processors to:
based on a determination that the setpoint value of the adjustable attribute is not valid, present, via the user interface, an alert.
